(19) United States
(12) Patent Application Publication
(10) Pub. No.: US 2026/0095141 A1
(43) Pub. Date: Apr. 2, 2026

(54) ACOUSTIC WAVE DEVICE AND ACOUSTIC WAVE FILTER DEVICE

(71) Applicant: Murata Manufacturing Co., Ltd., Nagaokakyo-shi (JP)

(72) Inventors: Akihiro IYAMA, Nagaokakyo-shi (JP); Yuta ISHII, Nagaokakyo-shi (JP); Katsuya DAIMON, Nagaokakyo-shi (JP)

(21) Appl. No.: 19/412,087

(22) Filed: Dec. 8, 2025

Related U.S. Application Data
(63) Continuation of application No. PCT/JP2024/021375, filed on Jun. 12, 2024.

(30) Foreign Application Priority Data
Jun. 13, 2023 (JP) 2023-097134

(51) Int. Cl. H03H 9/02; H03H 9/56

(52) U.S. Cl. CPC H03H 9/02157; H03H 9/02015; H03H 9/02228; H03H 9/568

(57) ABSTRACT

An acoustic wave device includes a piezoelectric layer including first and second major surfaces, an IDT electrode on one of the first and second major surfaces, and including electrode fingers arranged in an arrangement direction, and a support facing the second major surface, and including an acoustic reflection portion facing the second major surface. The electrode fingers include a first electrode finger at an outermost position in the arrangement direction and a second electrode finger adjacent thereto. A product of a width, height, and density of one of the first and second electrode fingers is greater than a product of a width, height, and density of a central electrode finger. When the thickness of the piezoelectric layer is denoted by d and a center-to-center distance between adjacent electrode fingers is denoted by p, d/p is less than or equal to about 0.5.

### CROSS REFERENCE TO RELATED APPLICATIONS

This application claims the benefit of priority to Japanese Patent Application No. 2023-097134 filed on Jun. 13, 2023 and is a Continuation Application of PCT Application No. PCT/JP2024/021375 filed on Jun. 12, 2024. The entire contents of each application are hereby incorporated herein by reference.

### BACKGROUND OF THE INVENTION

### 1. Field of the Invention

The present invention relates to acoustic wave devices and acoustic wave filter devices.

### 2. Description of the Related Art

Japanese Unexamined Patent Application Publication No. 2022-524136 and U.S. Pat. No. 11,349,450 describe acoustic wave devices.

The acoustic wave devices disclosed in Japanese Unexamined Patent Application Publication No. 2022-524136 and U.S. Pat. No. 11,349,450 have the potential to exhibit ripples in the admittance characteristics, which can lead to increased acoustic wave propagation loss.

### SUMMARY OF THE INVENTION

Example embodiments of the present invention provide acoustic wave devices and acoustic wave filter devices that are each able to reduce or prevent acoustic wave propagation loss.

An acoustic wave device according to an example embodiment of the present invention includes a piezoelectric layer including a first major surface and a second major surface opposite the first major surface in a first direction, an interdigital transducer (IDT) electrode on at least one of the first major surface or the second major surface of the piezoelectric layer, the IDT electrode including a plurality of electrode fingers arranged in an arrangement direction, and a support facing the second major surface of the piezoelectric layer and including an acoustic reflection portion on a side facing the second major surface of the piezoelectric layer. The plurality of electrode fingers include a first electrode finger located at an outermost position in the arrangement direction of the plurality of electrode fingers and a second electrode finger adjacent to the first electrode finger. A product of a width, a height, and a density of at least one of the first electrode finger or the second electrode finger is greater than a product of a width, a height, and a density of a central electrode finger different from the first electrode finger and the second electrode finger among the plurality of electrode fingers. When a thickness of the piezoelectric layer is denoted by d and a center-to-center distance between adjacent electrode fingers among the plurality of electrode fingers is denoted by p, d/p is less than or equal to about 0.5.

An acoustic wave device according to another example embodiment of the present invention includes a piezoelectric layer including a first major surface and a second major surface opposite the first major surface in a first direction, an IDT electrode on at least one of the first major surface or the second major surface of the piezoelectric layer, the IDT electrode including a plurality of electrode fingers arranged in an arrangement direction, a support facing the second major surface of the piezoelectric layer and including an acoustic reflection portion on a side facing the second major surface of the piezoelectric layer, and an additional electrode in a region overlying at least one of a first electrode finger or a second electrode finger, the first electrode finger being an electrode finger among the plurality of electrode fingers located at an outermost position in the arrangement direction, the second electrode finger being an electrode finger adjacent to the first electrode finger among the plurality of electrode fingers. A sum of a product of a width, a height, and a density of at least one of the first electrode finger or the second electrode finger and a product of a width, a height, and a density of the additional electrode is greater than a product of a width, a height, and a density of a central electrode finger different from the first electrode finger and the second electrode finger among the plurality of electrode fingers. When a thickness of the piezoelectric layer is denoted by d and a center-to-center distance between adjacent electrode fingers among the plurality of electrode fingers is denoted by p, d/p is less than or equal to about 0.5.

An acoustic wave filter device according to another example embodiment of the present invention includes at least one resonator coupled thereto. The resonator corresponds to an acoustic wave device according to an example embodiment of the present invention.

Acoustic wave devices and acoustic wave filter devices according to example embodiments of the present invention are each able to reduce or prevent acoustic wave propagation loss.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of an acoustic wave device according to a first example embodiment of the present invention.

FIG. 2 is a sectional view taken along II-II′ in FIG. 1.

FIG. 3 is a schematic sectional view illustrating a bulk wave of a first thickness-shear mode propagating through a piezoelectric layer according to the first example embodiment of the present invention.

FIG. 4 is a schematic sectional view illustrating an amplitude direction of a bulk wave of a first thickness-shear mode propagating through a piezoelectric layer according to the first example embodiment of the present invention.

FIG. 5 illustrates an example of a resonance characteristic of the acoustic wave device according to the first example embodiment of the present invention.

FIG. 6 illustrates a relationship between d/2p and a fractional band width of the acoustic wave device according to the first example embodiment as a resonator, where a center-to-center distance between adjacent electrodes or an average distance of center-to-center distances between adjacent electrodes is p and an average thickness of the piezoelectric layer is d.

FIG. 7 is a plan view of the acoustic wave device according to the first example embodiment in which a single pair of electrodes is provided.

FIG. 8 is a reference diagram illustrating an example of a resonance characteristic of the acoustic wave device according to the first example embodiment of the present invention.

FIG. 9 illustrates a relationship between a fractional band width and a phase rotation of a spurious impedance, normalized by about 180 degrees, representing a magnitude of a spurious signal in the acoustic wave device according to the first example embodiment, when many acoustic wave resonators are configured.

FIG. 10 illustrates a relationship among d/2p, a metallization ratio MR, and a fractional band width.

FIG. 11 illustrates a map of a fractional band width with respect to Euler angles (0°, θ, ψ) of lithium niobate, when d/p is set as close to 0 as possible.

FIG. 12 illustrates an enlarged sectional view of the region A illustrated in FIG. 2.

FIG. 13 illustrates an example of an admittance characteristic of the acoustic wave device according to the first example embodiment of the present invention.

FIG. 14 illustrates an example of an admittance characteristic of an acoustic wave device according to a first modification of the first example embodiment of the present invention.

FIG. 15 illustrates an example of an admittance characteristic of an acoustic wave device according to a second modification of the first example embodiment of the present invention.

FIG. 16 is a sectional view illustrating an acoustic wave device according to a third modification of the first example embodiment of the present invention.

FIG. 17 illustrates an example of an admittance characteristic of the acoustic wave device according to the third modification of the first example embodiment of the present invention.

FIG. 18 is a sectional view illustrating an acoustic wave device according to a fourth modification of the first example embodiment of the present invention.

FIG. 19 illustrates an example of an admittance characteristic of the acoustic wave device according to the fourth modification of the first example embodiment of the present invention.

FIG. 20 is a sectional view illustrating an acoustic wave device according to a second example embodiment of the present invention.

FIG. 21 illustrates an example of an admittance characteristic of the acoustic wave device according to the second example embodiment of the present invention.

FIG. 22 is a sectional view illustrating an acoustic wave device according to a fifth modification of the second example embodiment of the present invention.

FIG. 23 is a sectional view illustrating an acoustic wave device according to a sixth modification of the second example embodiment of the present invention.

FIG. 24 illustrates an example of an admittance characteristic of the acoustic wave device according to the sixth modification of the second example embodiment of the present invention.

FIG. 25 illustrates a vibration mode distribution of the acoustic wave device according to the sixth modification of the second example embodiment of the present invention.

FIG. 26 illustrates a vibration mode distribution of an acoustic wave device according to a comparative example.

FIG. 27 is a sectional view illustrating an acoustic wave device according to a seventh modification of the second example embodiment of the present invention.

FIG. 28 is a sectional view illustrating an acoustic wave device according to an eighth modification of the second example embodiment of the present invention.

FIG. 29 is a circuit diagram of an acoustic wave device according to a third example embodiment of the present invention.

FIG. 30 is a sectional view illustrating an acoustic wave device according to a ninth modification of an example embodiment of the present invention.

FIG. 31 is a sectional view illustrating an acoustic wave device according to a tenth modification of an example embodiment of the present invention.

FIG. 32 is a plan view illustrating an acoustic wave device according to an eleventh modification of an example embodiment of the present invention.

FIG. 33 illustrates an example of an admittance characteristic of an acoustic wave device according to a twelfth modification of an example embodiment of the present invention.

FIG. 34 illustrates an example of impedance phase for the S2 mode.

### DETAILED DESCRIPTION OF THE EXAMPLE EMBODIMENTS

Hereinafter, example embodiments of the present disclosure will be described in detail below with reference to the drawings. The present invention is not limited by the example embodiments. The example embodiments described in the present disclosure are merely examples, and configurational features of different example embodiments may be partially replaced or combined. In the modifications and the second and subsequent example embodiments, descriptions of the features common to the first example embodiment will not be repeated, and only different features will be described. In particular, the same or substantially the same advantageous effects achieved by the same or substantially the same configurational features will not be described in every example embodiment.

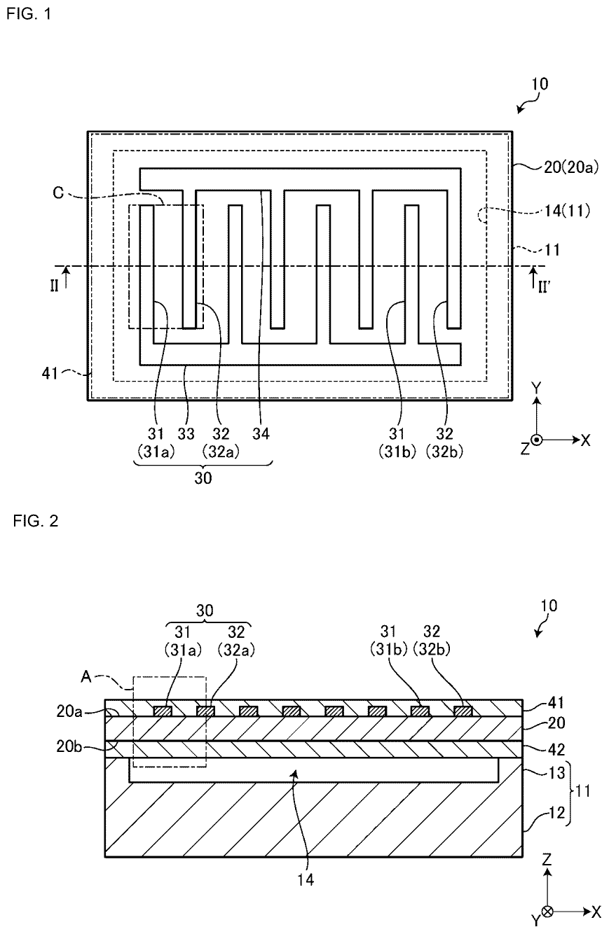

FIG. 1 is a plan view of an acoustic wave device according to a first example embodiment of the present invention. FIG. 2 is a sectional view taken along II-II′ in FIG. 1. In FIG. 1, a first protective film 41 is illustrated with a two-dot chain line for ease of viewing the drawing.

As illustrated in FIGS. 1 and 2, an acoustic wave device 10 according to the first example embodiment includes a piezoelectric layer 20, an interdigital transducer (IDT) electrode 30, a support substrate 11, the first protective film 41, and a second protective film 42. As illustrated in FIG. 2, the acoustic wave device 10 is formed by stacking the second protective film 42, the piezoelectric layer 20, the IDT electrode 30, and the first protective film 41 in this order on the support substrate 11.

The piezoelectric layer 20 is formed as a plate including a first major surface 20a and a second major surface 20b opposite the first major surface 20a. The piezoelectric layer 20 includes, for example, lithium niobate. Alternatively, the piezoelectric layer 20 may include, for example, lithium tantalate. In the first example embodiment, the cut-angle of lithium niobate or lithium tantalate is a Z-cut. The cut-angle of lithium niobate or lithium tantalate may be a rotated Y-cut or X-cut. Preferably, the propagation direction is, for example, within about ±30° with respect to Y-propagation or X-propagation. Preferably, for example, the piezoelectric layer 20 includes lithium niobate or lithium tantalate and has a about 120°±10° rotated Y-cut or a 90°±10° rotated Y-cut.

The thickness of the piezoelectric layer 20 is not particularly limited. However, the thickness is, for example, preferably within the range from about 50 nm to about 1000 nm inclusive to achieve effective oscillation in the first thickness-shear mode. The film thickness of the piezoelectric layer 20 in the first example embodiment is, for example, about 180 nm.

The interdigital transducer (IDT) electrode 30 is provided on the first major surface 20a of the piezoelectric layer 20. As illustrated in FIG. 1, the IDT electrode 30 includes electrode fingers 31 and 32 and busbar electrodes 33 and 34. The electrode fingers 31 extend in the Y direction. One end of each electrode finger 31 in the extension direction is connected to the busbar electrode 33. The electrode fingers 32 extend in the Y direction. The other end of each electrode finger 32 in the extension direction is connected to the busbar electrode 34. The electrode fingers 31 and 32 are alternately arranged in the X direction with spaces therebetween. The busbar electrodes 33 and 34 extend in the X direction and are spaced apart in the Y direction. The electrode fingers 31 and 32 are arranged between the busbar electrodes 33 and 34.

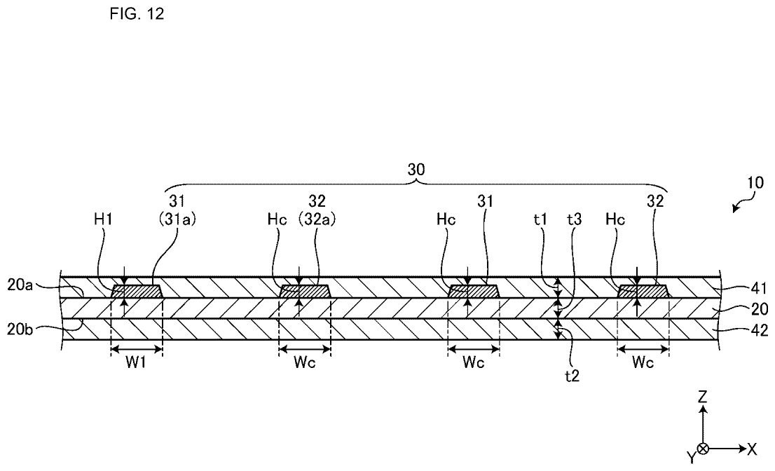

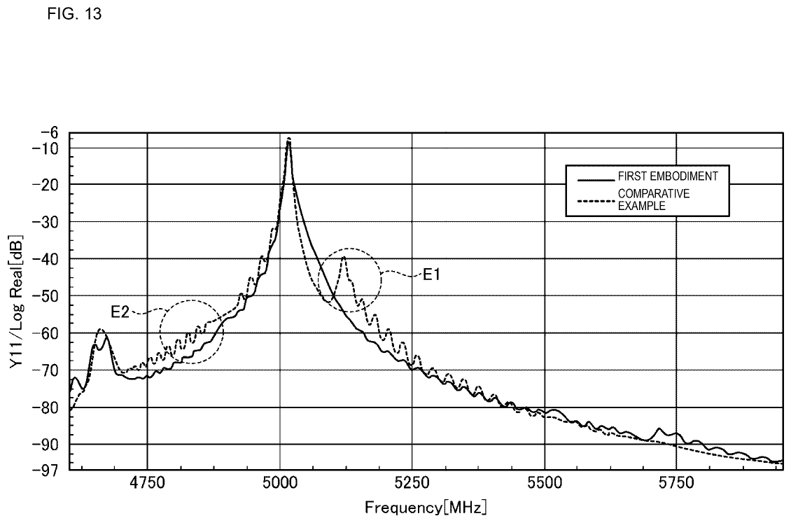

Of the electrode fingers 31 and 32, the electrode finger 31 located at the outermost position in the arrangement direction of the electrode fingers 31 and 32 is referred to as the first electrode finger 31a. The electrode finger 32 adjacent to the first electrode finger 31a, that is, the electrode finger 32 located at the second outermost position in the arrangement direction, is referred to as the second electrode finger 32a. The pair of electrode fingers 31 and 32 located at the outermost position on the opposite side of the first electrode finger 31a and the second electrode finger 32a are referred to respectively as the third electrode finger 31b and the fourth electrode finger 32b. The detailed configuration of the first electrode finger 31a, the second electrode finger 32a, the third electrode finger 31b, and the fourth electrode finger 32b will be described below with reference to FIGS. 12 and 13.

In the following description, the thickness direction of the piezoelectric layer 20 is sometimes described as the Z direction, the extension direction of the electrode fingers 31 and 32 as the Y direction, and the arrangement direction of the electrode fingers 31 and 32 as the X direction. In the following description, a plan view refers to the positional relationship when viewed in a direction perpendicular or substantially perpendicular to the first major surface 20a of the piezoelectric layer 20.

The center-to-center distance between the electrode fingers 31 and 32 (hereinafter referred to as inter-electrode pitch) is preferably within the range from 1 μm to 10 μm inclusive. The inter-electrode pitch is the distance between the center of the width dimension of an electrode finger 31 in the direction orthogonal or substantially orthogonal to the extension direction of the electrode finger 31 and the center of the width dimension of an electrode finger 32 in the direction orthogonal or substantially orthogonal to the extension direction of the electrode finger 32. The widths of the electrode fingers 31 and 32 (hereinafter referred to as electrode width), that is, the dimensions in the direction orthogonal or substantially orthogonal to the extension direction of the electrode fingers 31 and 32, are preferably within the range from, for example, about 150 nm to about 1000 nm inclusive.

In the case where at least multiple electrode fingers 31 or 32 are provided (assuming that one electrode pair includes electrode fingers 31 and 32, in the case where one and a half or more electrode pairs are provided), the inter-electrode pitch between the electrode fingers 31 and 32 is defined as the average of the center-to-center distances between adjacent electrode fingers 31 and 32 among the electrode fingers 31 and 32 of the one and a half or more electrode pairs.

Since a Z-cut piezoelectric layer is used in the first example embodiment, the direction orthogonal or substantially orthogonal to the extension direction of the electrode fingers 31 and 32 is orthogonal or substantially orthogonal to the polarization direction of the piezoelectric layer 20. The same does not apply when piezoelectric materials having other cut-angles are used as the piezoelectric layer 20. As used herein, “orthogonal” is not limited to being strictly orthogonal, but also includes substantially orthogonal orientations (for example, the angle between the direction orthogonal to the extension direction of the electrode fingers 31 and 32 and the polarization direction may be about 90°±10°).

The IDT electrodes 30 (the electrode fingers 31, 32 and the busbar electrodes 33, 34) are made of suitable metals or alloys such as, for example, aluminum or an aluminum-copper alloy. In the first example embodiment, the IDT electrode 30 has a structure including a stack of an aluminum film on a titanium film. An adhesion layer other than a titanium film may be used.

More specifically, the electrode configuration of the IDT electrode 30 is a monolithic film stack including titanium/aluminum-copper alloy/titanium/aluminum-copper alloy layers stacked in this order, starting from the piezoelectric layer 20. The respective film thicknesses are, for example, about 12 nm/about 70 nm/about 18 nm/about 12 nm. The total number of electrode fingers 31 and 32 of the IDT electrode 30 is, for example, 51. The inter-electrode pitch between electrode fingers 31 and 32 is, for example, about 2.38 μm. The electrode width of each electrode finger is, for example, about 0.6 μm.

An overlap region C (excitation region) illustrated in FIG. 1 is the region where the electrode fingers 31 and 32 overlap as viewed in the X direction. The length of the overlap region C is defined as the dimension of electrode fingers 31 and 32 in the extension direction within the overlap region C. In the present example embodiment, the length of the overlap region C is, for example, about 40 μm.

In order to drive the device, an alternating-current (AC) voltage is applied between the electrode fingers 31 and 32. More specifically, an AC voltage is applied between the busbar electrode 33 and 34. As a result, a resonance characteristic can be achieved by using bulk waves of the first thickness-shear mode excited in the piezoelectric layer 20.

In the acoustic wave device 10, when the thickness of the piezoelectric layer 20 is denoted by d and the inter-electrode pitch of multiple pairs of the electrode fingers 31 and 32 is denoted by p, d/p is, for example, less than or equal to about 0.5. With this configuration, bulk waves of the first thickness-shear mode can be effectively excited, and a favorable resonance characteristic can be achieved. More preferably, for example, d/p is less than or equal to about 0.24. In this case, a more favorable resonance characteristic can be achieved.

Since the acoustic wave device 10 of the first example embodiment has the configuration described above, when the number of pairs of electrode fingers 31 and 32 is reduced to achieve miniaturization, a decrease in the Q factor is less likely to occur. This result is due to decreased propagation loss, because the resonator does not require reflectors on both sides. The resonator does not require reflectors because bulk waves of the first thickness-shear mode are used.

The first protective film 41 is provided on the first major surface 20a of the piezoelectric layer 20 to cover the IDT electrode 30. The second protective film 42 is provided on the second major surface 20b of the piezoelectric layer 20. The first protective film 41 and the second protective film 42 are made of silicon oxide, for example. The first protective film 41 and the second protective film 42 may be made of suitable insulating materials other than silicon oxide, such as, for example, silicon nitride or alumina. The film thickness of the first protective film 41 and the second protective film 42 are both thicker than the film thickness of the IDT electrode 30. The first protective film 41 and the second protective film 42 each have a film thickness of, for example, about 142 nm. It is sufficient that at least one of the first protective film 41 or the second protective film 42 is provided. For example, the configuration may be such that the first protective film 41 is provided without providing the second protective film 42.

The support substrate 11 (support) faces the second major surface 20b of the piezoelectric layer 20. The support substrate 11 includes a cavity portion 14 (hollow portion) on the surface facing the second major surface 20b of the piezoelectric layer 20. More specifically, the support substrate 11 includes a base portion 12 and a wall portion 13 provided on the upper surface of the base portion 12 to define a frame. The cavity portion 14 is provided in the space enclosed by the base portion 12 and the wall portion 13. The piezoelectric layer 20 is disposed on the upper surface of the wall portion 13 of the support substrate 11, with the second protective film 42 interposed therebetween. As described above, the acoustic wave device 10 includes a membrane structure with the cavity portion 14 (hollow portion) provided on the side facing the second major surface 20b of the piezoelectric layer 20. The support may include the support substrate 11 and an intermediate (insulating) layer.

The cavity portion 14 is provided so that vibrations in the overlap region C of the piezoelectric layer 20 are not obstructed. The second protective film 42 covers the opening of the cavity portion 14. However, as described above, the second protective film 42 is not required. In this case, the support substrate 11 may be disposed in direct contact with the second major surface 20b of the piezoelectric layer 20. Alternatively, the second protective film 42 may be provided in the region between the upper surface of the wall portion 13 and the second major surface 20b of the piezoelectric layer 20, while not being provided in the region overlying (lying over) the cavity portion 14. This means that the support substrate 11 may be disposed without direct contact with the second major surface 20b of the piezoelectric layer 2. In this case, the support substrate 11 and the intermediate layer may have a frame shape, thus providing the cavity portion 14. Alternatively, the intermediate layer may be provided with a recess, thus providing the cavity portion 14.

The support substrate 11 includes, for example, silicon. The orientation of the silicon plane on the side facing the piezoelectric layer 20 may be (100) or (110), or alternatively (111). Preferably, for example, high-resistance silicon with a resistivity of about 4 kΩ or higher is used. The support substrate 11 may also be made of suitable insulating or semiconductor materials. Examples of materials of the support substrate 11 include piezoelectric materials such as aluminum oxide, lithium tantalate, lithium niobate, or crystal, ceramics such as alumina, magnesia, sapphire, silicon nitride, aluminum nitride, silicon carbide, zirconia, cordierite, mullite, steatite, or forsterite, dielectric materials such as diamond or glass, or semiconductors such as gallium nitride.

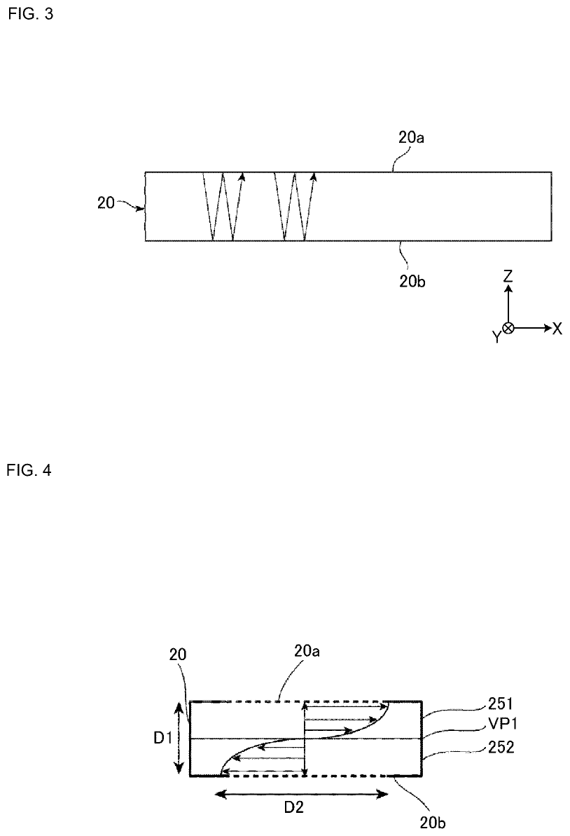

FIG. 3 is a schematic sectional view illustrating the bulk wave of the first thickness-shear mode propagating through the piezoelectric layer of the first example embodiment. FIG. 4 is a schematic sectional view illustrating the amplitude direction of the bulk wave of the first thickness-shear mode propagating through the piezoelectric layer of the first example embodiment.

As illustrated in FIG. 3, in the acoustic wave device 10 of the first example embodiment, since vibration displacement occurs in the thickness shear direction, the wave mainly propagates in the direction connecting the first major surface 20a and the second major surface 20b of the piezoelectric layer 20, that is, in the Z direction, thus causing resonance. This means that the X-direction component of the wave is significantly smaller than the Z-direction component. Since the resonance characteristic is obtained by propagation of the wave in the Z direction, no reflector is needed. As a result, propagation loss due to propagation to reflectors does not occur. Therefore, when the number of pairs of electrode fingers 31 and 32 is reduced for miniaturization, the Q factor is less likely to decrease.

As illustrated in FIG. 4, the amplitude direction of the bulk wave of the first thickness-shear mode in a first region 251 within the overlap region C (see FIG. 1) of the piezoelectric layer 20 is opposite to the amplitude direction of the bulk wave of the first thickness-shear mode in a second region 252 within the overlap region C. FIG. 4 schematically illustrates the bulk wave when a voltage is applied between the electrode fingers 31 and 32, in which the electrode fingers 32 are at a higher electric potential than the electrode fingers 31. An imaginary plane VP1 is orthogonal to the thickness direction of the piezoelectric layer 20 and divides the piezoelectric layer 20 into two portions. The first region 251 is located between the imaginary plane VP1 and the first major surface 20a within the overlap region C. The second region 252 is located between the imaginary plane VP1 and the second major surface 20b within the overlap region C.

In the acoustic wave device 10, at least one pair of electrodes including electrode fingers 31 and 32 is provided. Since the acoustic wave device 10 is not designed to propagate the wave in the X direction, multiple pairs of electrodes including electrode fingers 31 and 32 are not required. This means that at least one pair of electrodes is sufficient.

For example, the electrode fingers 31 are connected to a hot potential, while the electrode fingers 32 are connected to ground potential. Alternatively, the electrode fingers 31 may be connected to ground potential, while the electrode fingers 32 to a hot potential. As described above, in the first example embodiment, at least one pair of electrodes is connected either to a hot potential or ground potential, and no floating electrodes are provided.

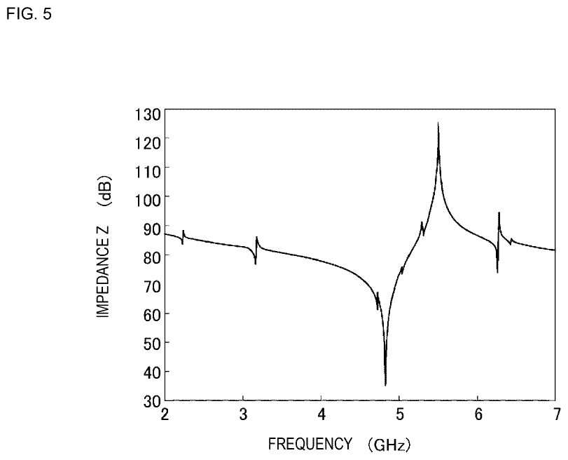

FIG. 5 illustrates an example of the resonance characteristic of the acoustic wave device of the first example embodiment. The design parameters of the acoustic wave device 10, which provides the resonance characteristic illustrated in FIG. 5, are as follows:
Piezoelectric layer 20: lithium niobate with Euler angles (0°, 0°, 90°)
Piezoelectric layer 20 thickness: about 400 nm
Overlap region C length: about 40 μm
Number of pairs of electrodes consisting of electrode fingers 31 and 32: 21 pairs
Inter-electrode pitch between electrode fingers 31 and 32: about 3 μm
Width of electrode fingers 31 and 32: about 500 nm
d/p: about 0.133
First protective film 41, second protective film 42: silicon oxide film with a thickness of about 1 μm
Support substrate 11: silicon

In the first example embodiment, the inter-electrode pitches of the electrode pairs consisting of electrode fingers 31 and 32 are the same or substantially the same for all pairs. In other words, the electrode fingers 31 and 32 are disposed at an identical or substantially identical pitch.

It is clear from FIG. 5 that a favorable resonance characteristic with a fractional band width of about 12.5% is achieved despite the absence of reflectors.

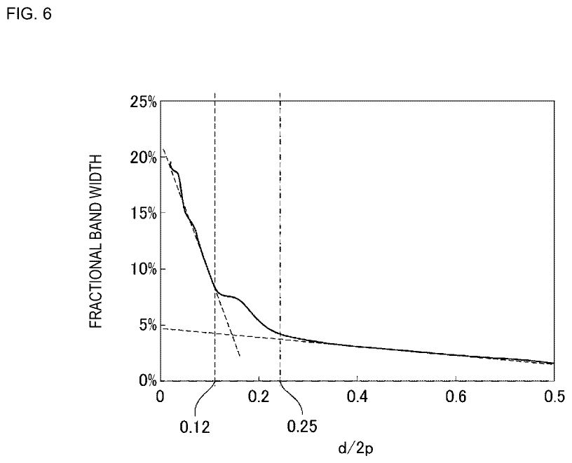

In the first example embodiment, for example, when the thickness of the piezoelectric layer 20 is d and the inter-electrode pitch of electrode fingers 31 and 32 is p, d/p is less than or equal to about 0.5, and more preferably less than or equal to about 0.24. This will be described with reference to FIG. 6.

FIG. 6 illustrates the relationship between d/2p and the fractional band width of the acoustic wave device of the first example embodiment as a resonator, where the center-to-center distance between adjacent electrodes or the average distance of center-to-center distances between adjacent electrodes is p and the average thickness of the piezoelectric layer is d. In FIG. 6, multiple acoustic wave devices were configured in the same or substantially the same manner as the acoustic wave device that provides the resonance characteristic illustrated in FIG. 5, while varying d/2p.

As illustrated in FIG. 6, when d/2p exceeds about 0.25, that is, when d/p>about 0.5, the fractional band width remains less than about 5% regardless of changes in d/p. In contrast, when d/2p≤about 0.25, that is, when d/p≤about 0.5, the fractional band width remains greater than or equal to about 5% as d/p varies within this range. This means that a resonator with a high coupling coefficient can be provided. When d/2p is less than or equal to about 0.12, that is, when d/p is less than or equal to about 0.24, the fractional band width increases to greater than or equal to about 7%. By changing d/p within this range, a resonator with a further increased fractional band width can be obtained, and a resonator with a further increased coupling coefficient can thus be achieved. Overall, it is understood that by setting d/p less than or equal to about 0.5, a resonator with a high coupling coefficient using the bulk wave of the first thickness-shear mode can be provided.

For the thickness d of the piezoelectric layer 20, when the piezoelectric layer 20 includes variations in thickness, an average value of the thicknesses may be used.

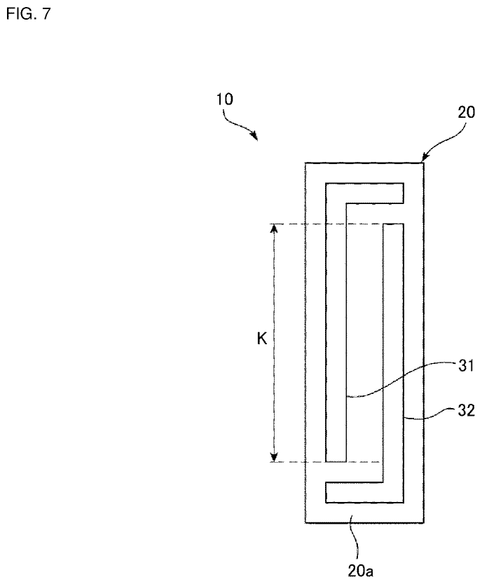

FIG. 7 is a plan view of the acoustic wave device of the first example embodiment in which a single pair of electrodes is provided. In the acoustic wave device 10, a single pair of electrodes consisting of electrode fingers 31 and 32 are provided on the first major surface 20a of the piezoelectric layer 20. In FIG. 7, K is the overlap width. As described above, in the acoustic wave device 10, the number of pairs of electrodes may include a single pair. In this case as well, when d/p, as described above, is less than or equal to about 0.5, the bulk wave of the first thickness-shear mode can be effectively excited.

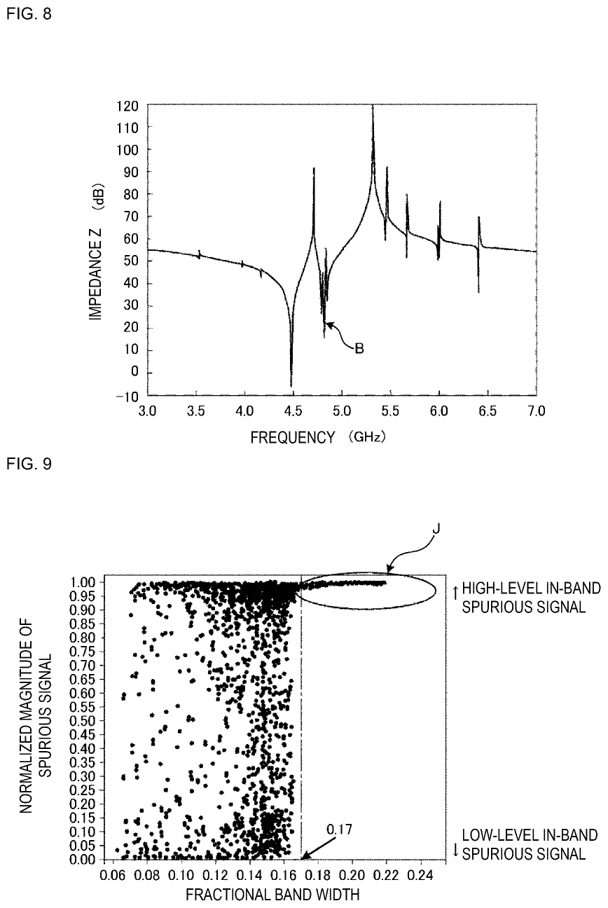

In the acoustic wave device 10, it is preferable that the metallization ratio MR of adjacent electrode fingers 31 and 32 in the overlap region C satisfies MR≤about 1.75(d/p)+0.075. In such cases, spurious signals can be effectively reduced. This is illustrated with reference to FIGS. 8 and 9.

FIG. 8 is a reference diagram illustrating an example of the resonance characteristic of the acoustic wave device of the first example embodiment. As illustrated in FIG. 8, the spurious signal indicated by an arrow B appears between the resonant and anti-resonant frequencies. d/p=about 0.08 and the Euler angles of lithium niobate are (0°, 0°, 90°). In addition, the metallization ratio MR=about 0.35.

The metallization ratio MR will be described with reference to FIG. 1. It is assumed that this pair of electrode fingers 31 and 32 include a single pair of electrode fingers 31 and 32 is focused on in the electrode configuration illustrated in FIG. 1. In this case, the portion surrounded by a dot-dash line is the overlap region C. This overlap region C is defined as the region observed when the electrode fingers 31 and 32 are viewed in the direction orthogonal to the extension direction of the electrode fingers 31 and 32, that is, in the direction in which the electrode fingers 31 and 32 face each other, including the region overlapping with the electrode finger 32 within the electrode finger 31, the region overlapping with the electrode finger 31 within the electrode finger 32, and the region in which the electrode fingers 31 and 32 overlap with each other within the region between the electrode fingers 31 and 32. The metallization ratio MR is defined as the area of the electrode fingers 31 and 32 within the overlap region C to the area of the overlap region C. This means that the metallization ratio MR is defined as the ratio of the area of the metallized portion to the area of the overlap region C.

When multiple pairs of electrode fingers 31 and 32 are provided, MR is defined as the ratio of the metallized portions included in the entire or substantially the entire overlap regions C to the total area of the overlap regions C.

FIG. 9 illustrates the relationship between the fractional band width and the phase rotation of the spurious impedance, normalized by about 180 degrees, representing the magnitude of the spurious signal in the acoustic wave device of the first example embodiment, when many acoustic wave resonators are provided. The fractional band width was changed by varying the film thickness of the piezoelectric layer 20 and the dimensions of the electrode fingers 31 and 32 in different manners. FIG. 9 illustrates results obtained in the case of using the piezoelectric layer 20 made of Z-cut lithium niobate. However, the same or similar tendency can also be observed when the piezoelectric layer 20 of other cut-angles is used.

In the region enclosed by an oval J in FIG. 9, the spurious signal reaches as high as about 1.0. As seen from FIG. 9, when the fractional band width exceeds about 0.17, that is, about 17%, spurious signals at levels of about 1 or higher are generated in the pass band, regardless of changes in parameters affecting the fractional band width. In other words, as illustrated in the resonance characteristic in FIG. 8, relatively large spurious signals, indicated by the arrow B, appear within the band width. Thus, for example, the fractional band width is preferably less than or equal to about 17%. In this case, spurious signals can be reduced by changing factors such as the film thickness of the piezoelectric layer 20 and the dimensions of the electrode fingers 31 and 32.

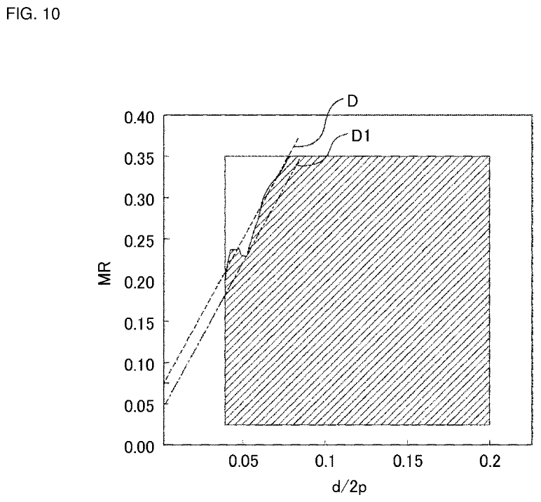

FIG. 10 illustrates the relationship among d/2p, the metallization ratio MR, and the fractional band width. The fractional band width was measured by configuring various acoustic wave devices 10 of the first example embodiment with different d/2p and MR values. The hatched portion on the right side of the dashed line D in FIG. 10 indicates the region in which the fractional band width is less than or equal to about 17%. The boundary between this hatched region and the non-hatched region is provided by MR=about 3.5(d/2p)+0.075. That is, MR=about 1.75(d/p)+0.075. As a result, for example, it is preferable that MR≤about 1.75(d/p)+0.075. In this case, the fractional band width can be easily controlled to be less than or equal to about 17%. The region on the right side of the dot-dash line D1 in FIG. 10 is more preferable. The dot-dash line D1 indicates that MR=about 3.5 (d/2p)+0.05. Overall, when MR≤about 1.75 (d/p)+0.05, the fractional band width is ensured to be less than or equal to about 17%.

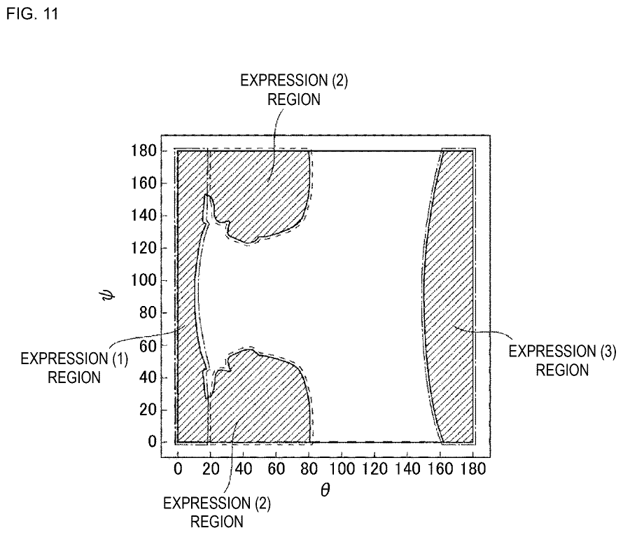

FIG. 11 illustrates a map of the fractional band width with respect to Euler angles (0°, θ, ψ) of lithium niobate, when d/p is set as close to 0 as possible. The hatched portions in FIG. 11 indicate the regions in which a fractional band width of at least about 5% or greater can be obtained. By approximating the ranges of the regions, the ranges can be represented by the following expressions (1), (2), and (3):

(0°±10°, 0° to 20°, any ψ) . . . Expression (1)

(0°±10°, 20° to 80°, 0° to 60°(1−(θ−50)²/900)^{1/2}) or (0°±10°, 20° to 80°, [180°-60°(1−(θ−50)²/900)^{1/2}] to 180°) . . . Expression (2)

(0°±10°, [180°-30°(1−(ψ−90)²/8100)^{1/2}] to 180°, any ψ) . . . Expression (3)

The Euler angle region defined by Expression (1), (2), or (3) is preferable because the fractional band width can be adequately increased.

Next, a detailed configuration of the IDT electrode 30 will be described. FIG. 12 illustrates an enlarged sectional view of the region A illustrated in FIG. 2. FIG. 12 illustrates the first electrode finger 31a, which is located at the outermost position in the arrangement direction of the multiple electrode fingers 31 and 32, as well as the second electrode finger 32a adjacent to the first electrode finger 31a. The third electrode finger 31b and the fourth electrode finger 32b (see FIGS. 1 and 2), which are located at the outermost position, opposite to the first electrode finger 31a and the second electrode finger 32a, are line-symmetrical to the first electrode finger 31a and the second electrode finger 32a in the positional relationship. The description of the first electrode finger 31a and the second electrode finger 32a also applies to the third electrode finger 31b and the fourth electrode finger 32b. In the following description, when it is not necessary to separately describe the first electrode finger 31a and the second electrode finger 32a, the first electrode finger 31a and the second electrode finger 32a are simply referred to as the electrode fingers 31 and 32.

As illustrated in FIG. 12, the first electrode finger 31a and the second electrode finger 32a, as well as central electrode fingers 31 and 32 other than the first electrode finger 31a and the second electrode finger 32a that are located in the central region, are provided in the same layer on the first major surface 20a of the piezoelectric layer 20. The first protective film 41 is provided to cover the first electrode finger 31a and the second electrode finger 32a, as well as the central electrode fingers 31 and 32. In the present example embodiment, the upper surface of the first protective film 41 is flat. The lower surface of the second protective film 42 is flat, lying along the second major surface 20b of the piezoelectric layer 20.

As described above, the film thickness t1 of the first protective film 41 and the film thickness t2 of the second protective film 42 are each, for example, about 142 nm. The film thickness t3 of the piezoelectric layer 20 is, for example, about 180 nm. The film thickness t1 of the first protective film 41 is equal or substantially equal to the film thickness t2 of the second protective film 42. The film thickness t1 of the first protective film 41 is smaller than the film thickness t3 of the piezoelectric layer 20 and thicker than the heights H1 and Hc (film thickness) of the IDT electrode 30.

As illustrated in FIG. 12, the product Xe (=W1×H1×d1) of the width W1, the height H1, and the density d1 of at least one of the first electrode finger 31a or the second electrode finger 32a is greater than the product Xc (=Wc×Hc×dc) of the width Wc, the height Hc, and the density dc of the central electrode fingers 31 and 32 other than the first electrode finger 31a and the second electrode finger 32a among the multiple electrode fingers 31 and 32. In the following description, the products Xe and Xc are each calculated for a single electrode finger 31 and a single electrode 32. The term “density” as used in the present example embodiment, unless otherwise specified, refers to a material-specific physical property. The densities of the materials used for the electrode fingers 31 and 32 are described below. Tungsten: 19.3 g/cm³, molybdenum: 10.22 g/cm³, ruthenium: 12.41 g/cm³, platinum: 21.45 g/cm³, copper: 8.96 g/cm³, silver: 10.5 g/cm³, chromium: 7.189 g/cm³, gold 19.32 g/cm³.

In the present example embodiment, the product Xe (=W1×H1×d1) of the first electrode finger 31a, which is located at the outermost position among the first electrode finger 31a and the second electrode finger 32a in the arrangement direction, is greater than the product Xc (=Wc×Hc×dc) of each of the second electrode finger 32a, which is adjacent to the first electrode finger 31a, and the central electrode fingers 31 and 32. In the following description, the second electrode finger 32a adjacent to the first electrode finger 31a, as well as the central electrode fingers 31 and 32, are referred to as other electrode fingers 31 and 32.

In an example, the width W1 of the first electrode finger 31a is equal or substantially equal to the width Wc of each of the other electrode fingers 31 and 32 (the second electrode finger 32a and the central electrode fingers 31 and 32). For example, the widths W1 and Wc are each about 0.6 μm.

The first electrode finger 31a, which is located at the outermost position among the first electrode finger 31a and the second electrode finger 32a in the arrangement direction, is made of a material with a higher density than the central electrode fingers 31 and 32. The first electrode finger 31a includes a single layer of platinum, for example. The density d1 of the first electrode finger 31a (platinum) is about 21450 kg/m³, for example. Each of the other electrode fingers 31 and 32 is, for example, a monolithic film stack including titanium/aluminum-copper alloy/titanium/aluminum-copper alloy layers as described above. The density of the aluminum-copper alloy of the other electrode fingers 31 and 32 is, for example, about 2695 kg/m³ and the density of titanium is, for example, about 4500 kg/m³. The density d1 of the first electrode finger 31a is greater than the density dc of the other electrode fingers 31 and 32.

The height H1 (film thickness) of the first electrode finger 31a is, for example, about 112 nm. The respective film thicknesses of the layers of the monolithic film stack forming the second electrode finger 32a are, for example, about 12 nm/about 70 nm/about 18 nm/about 12 nm. This indicates that the height Hc (total film thickness) of the other electrode fingers 31 and 32 is, for example, about 112 nm. In the present example embodiment, the height H1 of the first electrode finger 31a is equal or substantially the same to the height Hc of the other electrode fingers 31 and 32, and the heights H1 and Hc are each about 112 nm, for example.

In an example, the product Xe (=W1×H1×d1) of the first electrode finger 31a is Xe=0.6 (μm)×0.112 (μm)×21450 (kg/m³)=1441.44. The product Xc (=Wc×Hc×dc) of the other electrode fingers 31 and 32 is Xc=0.6 (μm)×0.03 (μm)×4500 (kg/m³)+0.6 (μm)×0.082 (μm)×2695 (kg/m³)=213.594.

FIG. 13 illustrates an example of the admittance characteristic of the acoustic wave device according to the first example embodiment. FIG. 13 illustrates the real part of the admittance, that is, the conductance component, of the acoustic wave device 10 of the first example embodiment. The admittance characteristic illustrated in FIG. 13 represents a simulation result of the admittance characteristic of the acoustic wave device 10 according to the first example embodiment. FIG. 13 also illustrates a simulation result of the admittance characteristic of an acoustic wave device according to a comparative example. The comparative example provides an acoustic wave device having a configuration in which the product Xe (=W1×H1×d1) of the first electrode finger 31a, located at the outermost position in the arrangement direction, is equal or substantially equal to the product Xc (=Wc×Hc×dc) of each of the other electrode fingers 31 and 32, in contrast to the first example embodiment. More specifically, the comparative example provides an acoustic wave device with the first electrode finger 31a having a structure including a monolithic film stack including titanium/aluminum-copper alloy/titanium/aluminum-copper alloy layers, similar to the other electrode fingers 31 and 32.

As illustrated in FIG. 13, the acoustic wave device according to the comparative example exhibits ripples in a frequency region different from the resonant frequency. In the comparative example, in particular, a large ripple indicated by the dotted line E1 is generated. In contrast, in the acoustic wave device 10 according to the first example embodiment, the product Xe of the first electrode finger 31a is greater than the product Xc of each of the other electrode fingers 31 and 32. As a result, it can be seen that the ripple indicated by the dotted line E1 is reduced or prevented compared to the comparative example. In addition, the propagation loss in the frequency range indicated by the dotted line E2 is reduced or prevented in the acoustic wave device 10 of the first example embodiment compared to the comparative example. The acoustic wave device 10 according to the first example embodiment has a narrower peak width at the resonant frequency than the acoustic wave device according to the comparative example. This narrower peak width reduces propagation loss, thus mitigating acoustic wave leakage.

In the first example embodiment, the density d1 of the first electrode finger 31a is greater than the density d2 of the other electrode fingers 31 and 32, while the width W1 and height H1 of the first electrode finger 31a are equal or substantially equal to the width Wc and height Hc of the other electrode fingers 31 and 32. However, this should not be interpreted as limiting. The density d1 of the first electrode finger 31a may be equal or substantially equal to the density d2 of the other electrode fingers 31 and 32, while the width W1 of the first electrode finger 31a may be greater than the width Wc of the other electrode fingers 31 and 32. Alternatively, the density d1 of the first electrode finger 31a may be equal or substantially equal to the density d2 of the other electrode fingers 31 and 32, while the height H1 of the first electrode finger 31a may be greater than the height Hc of the other electrode fingers 31 and 32. Two or more of the width W1, height H1, and density d1 of the first electrode finger 31a may differ from the corresponding width Wc, height Hc, and density dc of the other electrode fingers 31 and 32.

The materials of the multiple electrode fingers 31 and 32 of the IDT electrode 30 are merely an example and are not limited to this example. As the materials of the multiple electrode fingers 31 and 32 of the IDT electrode 30, for example, at least one of tungsten, molybdenum, ruthenium, platinum, copper, silver, chromium, gold, titanium, or aluminum may be used.

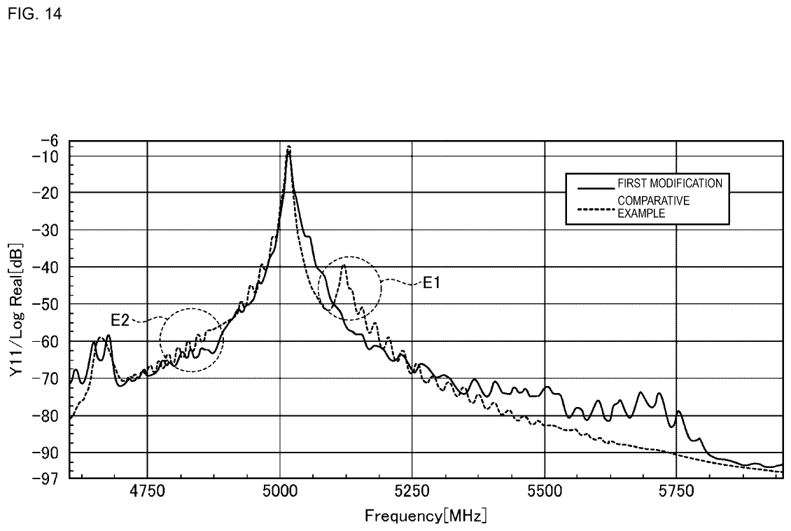

FIG. 14 illustrates an example of the admittance characteristic of an acoustic wave device according to a first modification of the first example embodiment. In the first example embodiment, a configuration is described in which the product Xe (=W1×H1×d1) of the first electrode finger 31a, which is located at the outermost position among the first electrode finger 31a and the second electrode finger 32a in the arrangement direction, is greater than the product Xc (=Wc×Hc×dc) of each of the other electrode fingers 31 and 32 (the second electrode finger 32a and the central electrode fingers 31 and 32). However, this should not be interpreted as limiting.

In the acoustic wave device according to the first modification, the product Xe (=W1×H1×d1) of both the first electrode finger 31a and the second electrode finger 32a, more specifically, each of the first electrode finger 31a located at the outermost position in the arrangement direction and the second electrode finger 32a adjacent to the first electrode finger 31a (the second electrode finger 32a located at the second outermost position in the arrangement direction) is greater than the product Xc (=Wc×Hc×dc) of each of the other electrode fingers 31 and 32 (the central electrode fingers 31 and 32).

In the first modification, the electrode configuration of the first electrode finger 31a and the second electrode finger 32a includes a single layer of platinum. The density d1 of the first electrode finger 31a and the density d1 of the second electrode finger 32a are greater than the density dc of the other electrode fingers 31 and 32. The width W1 of the first electrode finger 31a and the width W1 of the second electrode finger 32a are the same or substantially the same as the width Wc of the other electrode fingers 31 and 32 (the central electrode fingers 31 and 32). The height H1 of the first electrode finger 31a and the height H1 of the second electrode finger 32a are the same or substantially the same as the height Hc of the other electrode fingers 31 and 32 (the central electrode fingers 31 and 32).

Overall, the product Xe (=W1×H1×d1) of the first electrode finger 31a and the product Xe (=W1×H1×d1) of the second electrode finger 32a of the first modification are equal or substantially equal to the product Xe (=W1×H1×d1) of the first electrode finger 31a described in the first example embodiment. The product Xc (=Wc×Hc×dc) of each of the other electrode fingers 31 and 32 (the central electrode fingers 31 and 32) of the first modification is equal or substantially equal to the product Xc (=Wc×Hc×dc) of each of the other electrode fingers 31 and 32 (the second electrode finger 32a and the central electrode fingers 31 and 32) described in the first example embodiment.

As illustrated in FIG. 14, in the acoustic wave device according to the first modification, although the product Xe of each of the first electrode finger 31a and the second electrode finger 32a is greater than the product Xc of the other electrode fingers 31 and 32, at least the ripple indicated by the dotted line E1 is reduced or prevented compared to the comparative example, as in the first example embodiment. In the first modification as well, propagation loss is also reduced or prevented in the frequency range indicated by the dotted line E2.

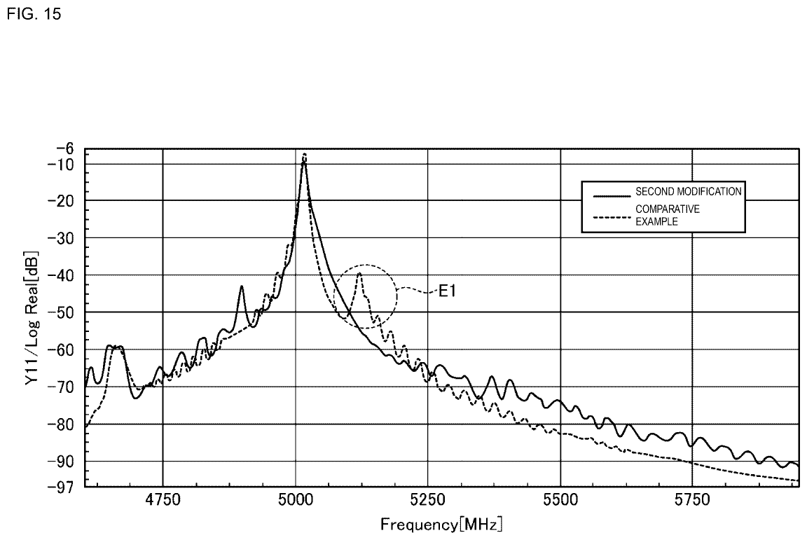

FIG. 15 illustrates an example of the admittance characteristic of an acoustic wave device according to a second modification of the first example embodiment. In the acoustic wave device according to the second modification, of the first electrode finger 31a and the second electrode finger 32a, the product Xe (=W1×H1×d1) of the second electrode finger 32a adjacent to the first electrode finger 31a located at the outermost position in the arrangement direction (the electrode finger 32 located at the second outermost position in the arrangement direction) is greater than the product Xc (=Wc×Hc×dc) of each of the other electrode fingers 31 and 32 (the first electrode finger 31a and the central electrode fingers 31 and 32).

In the second modification, for example, the first electrode finger 31a, located at the outermost position in the arrangement direction, is not a single layer of platinum, whereas the electrode configuration of the second electrode finger 32a, adjacent to the first electrode finger 31a, is a single layer of platinum. The density d1 of the second electrode finger 32a is greater than the density dc of the other electrode fingers 31 and 32 (the first electrode finger 31a and the central electrode fingers 31 and 32). The width W1 of the second electrode finger 32a is the same or substantially the same as the width Wc of the other electrode fingers 31 and 32 (the first electrode finger 31a and the central electrode fingers 31 and 32). The height H1 of the second electrode finger 32a is the same or substantially the same as the height Hc of the other electrode fingers 31 and 32 (the first electrode finger 31a and the central electrode fingers 31 and 32).

Overall, the product Xe (=W1×H1×d1) of the second electrode finger 32a of the second modification is equal or substantially equal to the product Xe (=W1×H1×d1) of the first electrode finger 31a described in the first example embodiment. The product Xc (=Wc×Hc×dc) of each of the other electrode fingers 31 and 32 (the first electrode finger 31a and the central electrode fingers 31 and 32) of the second modification is equal or substantially equal to the product Xc (=Wc×Hc×dc) of each of the other electrode fingers 31 and 32 (the second electrode finger 32a and the central electrode fingers 31 and 32) described in the first example embodiment.

As illustrated in FIG. 15, in the acoustic wave device according to the second modification, although the product Xe of the second electrode finger 32a, located at the second outermost position in the arrangement direction, is greater than the product Xc of the other electrode fingers 31 and 32, at least the ripple indicated by the dotted line E1 is reduced or prevented compared to the comparative example, as in the first example embodiment.

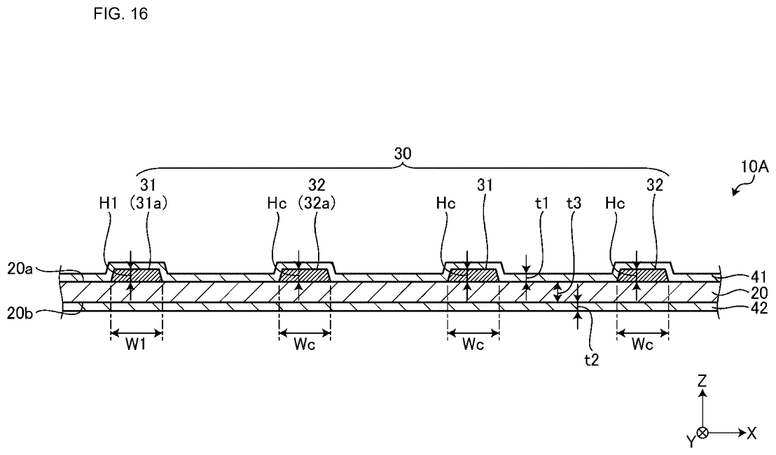

FIG. 16 is a sectional view illustrating an acoustic wave device according to a third modification of the first example embodiment. As illustrated in FIG. 16, in an acoustic wave device 10A according to the third modification, the film thickness t1 of the first protective film 41 and the film thickness t2 of the second protective film 42 are each smaller than the film thickness t3 of the piezoelectric layer 20. Specifically, the film thickness of the piezoelectric layer 20 is, for example, about 360 nm. The film thickness t1 of the first protective film 41 is, for example, about 30 nm. The film thickness t2 of the second protective film 42 is, for example, about 30 nm. The film thickness t1 of the first protective film 41 is smaller than the film thickness (the height H1, Hc) of the IDT electrode 30.

In the third modification, the first protective film 41 is provided to conform to the front and side surfaces of the electrode fingers 31 and 32, as well as to the first major surface 20a of the piezoelectric layer 20. Since the film thickness t1 of the first protective film 41 is small, recessed and raised portions are provided at the upper surface of the first protective film 41, reflecting the shape of the electrode fingers 31 and 32.

In the electrode configuration of the IDT electrode 30, as in the first example embodiment, the density d1 of the first electrode finger 31a is greater than the density d2 of the other electrode fingers 31 and 32, while the width W1 and height H1 of the first electrode finger 31a are equal or substantially equal to the width Wc and height Hc of the other electrode fingers 31 and 32. However, the film thicknesses differ from the first example embodiment described above.

Specifically, for example, in the third modification, the first electrode finger 31a, located at the outermost position in the arrangement direction, is a single layer of platinum and has the height H1 (film thickness) of about 69 nm. Each of the other electrode fingers 31 and 32 (the second electrode finger 32a and the central electrode fingers 31 and 32) is, for example, a monolithic film stack including titanium/aluminum-copper alloy/titanium/aluminum-copper alloy layers as described above. The respective film thicknesses are, for example, about 12 nm/about 27 nm/about 18 nm/about 12 nm. The height Hc (total film thickness) of each of the other electrode fingers 31 and 32 is, for example, about 69 nm.

In the third modification, the product Xe (=W1×H1×d1) of the first electrode finger 31a, which is located at the outermost position in the arrangement direction, is greater than the product Xc (=Wc×Hc×dc) of each of the other electrode fingers 31 and 32 (the second electrode finger 32a and the central electrode fingers 31 and 32.

The product Xe (=W1×H1×d1) of the first electrode finger 31a is, for example, Xe=0.6 (μm)×0.069 (μm)×21450 (kg/m³)=888.03. The product Xc (=Wc×Hc×dc) of the other electrode fingers 31 and 32 is, for example, Xc=0.6 (μm)×0.03 (μm)×4500 (kg/m³)+0.6 (μm)×0.039 (μm)×2695 (kg/m³)=144.063.

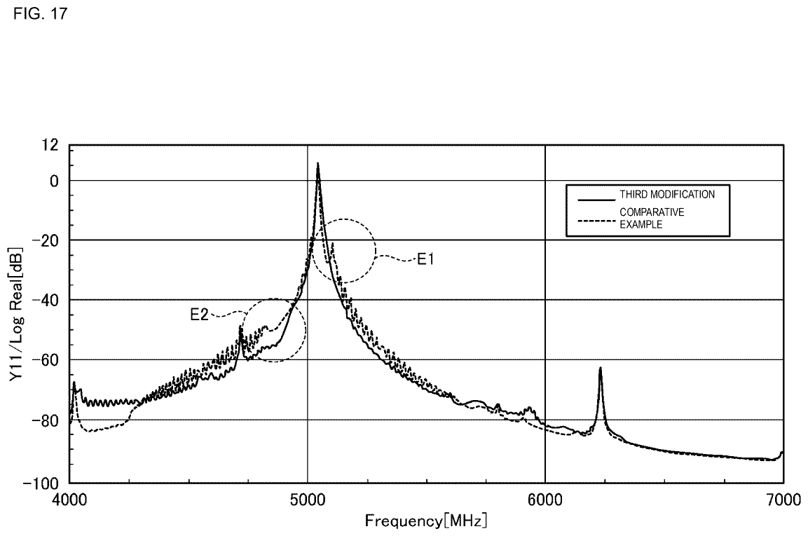

FIG. 17 illustrates an example of the admittance characteristic of the acoustic wave device according to the third modification of the first example embodiment. The comparative example illustrated in FIG. 17 provides the acoustic wave device 10A described in the third modification, in other words, the acoustic wave device 10A in which the film thicknesses t1 and t2 of the first protective film 41 and the second protective film 42 are each smaller than the film thickness t3 of the piezoelectric layer 20, and in which the first electrode finger 31a, located at the outermost position in the arrangement direction, has the same or substantially the same electrode configuration as the other electrode fingers 31 and 32.

As illustrated in FIG. 17, although the film thicknesses t1 and t2 of the first protective film 41 and the second protective film 42 are small, the ripples indicated by the dotted lines E1 and E2 are reduced or prevented in the acoustic wave device 10A described in the third modification compared to the comparative example, thus reducing or preventing propagation loss within the frequency range illustrated with the dotted line E2.

The electrode configuration of the IDT electrode 30 described in the third modification may be combined with the first modification or the second modification. Specifically, the product Xe (=W1×H1×d1) of each of the first electrode finger 31a and the second electrode finger 32a may be greater than the product Xc (=Wc×Hc×dc) of the other electrode fingers 31 and 32 (the central electrode fingers 31 and 32). Alternatively, the product Xe (=W1×H1×d1) of the second electrode finger 32a, located at the second outermost position in the arrangement direction, may be greater than the product Xc (=Wc×Hc×dc) of each of the other electrode fingers 31 and 32 (the first electrode finger 31a and the central electrode fingers 31 and 32).

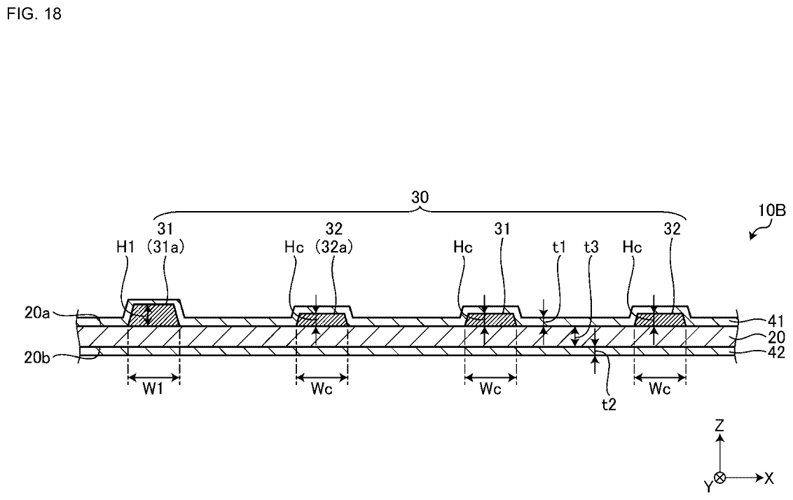

FIG. 18 is a sectional view illustrating an acoustic wave device according to a fourth modification of the first example embodiment. As illustrated in FIG. 18, in an acoustic wave device 10B according to the fourth modification, the height H1 of the first electrode finger 31a, located at the outermost position in the arrangement direction, is greater than the height Hc of the other electrode fingers 31 and 32 (the second electrode finger 32a and the central electrode fingers 31 and 32).

In the fourth modification, the width W1 of the first electrode finger 31a is equal or substantially equal to the width Wc of each of the other electrode fingers 31 and 32. The density d1 of the first electrode finger 31a is equal or substantially equal to the density dc of the other electrode fingers 31 and 32.

Specifically, for example, the first electrode finger 31a, located at the outermost position in the arrangement direction, is a single layer of aluminum and has the height H1 (film thickness) of about 100 nm. Each of the other electrode fingers 31 and 32 (the second electrode finger 32a and the central electrode fingers 31 and 32) is, for example, a monolithic film stack including titanium/aluminum-copper alloy/titanium/aluminum-copper alloy layers as described above. The respective film thicknesses are, for example, about 12 nm/about 27 nm/about 18 nm/about 12 nm. The height Hc (total film thickness) of each of the other electrode fingers 31 and 32 is, for example, about 69 nm.

The product Xe (=W1×H1×d1) of the first electrode finger 31a is, for example, Xe=0.6 (μm)×0.100 (μm)×2695 (kg/m³)=161.7. The product Xc (=Wc×Hc×dc) of the other electrode fingers 31 and 32 is the same or substantially the same as in the third modification, with Xc=144.063, for example.

As described above, in the fourth modification, the product Xe (=W1×H1×d1) of the first electrode finger 31a, which is located at the outermost position in the arrangement direction, is greater than the product Xc (=Wc×Hc×dc) of each of the other electrode fingers 31 and 32 (the second electrode finger 32a and the central electrode fingers 31 and 32).

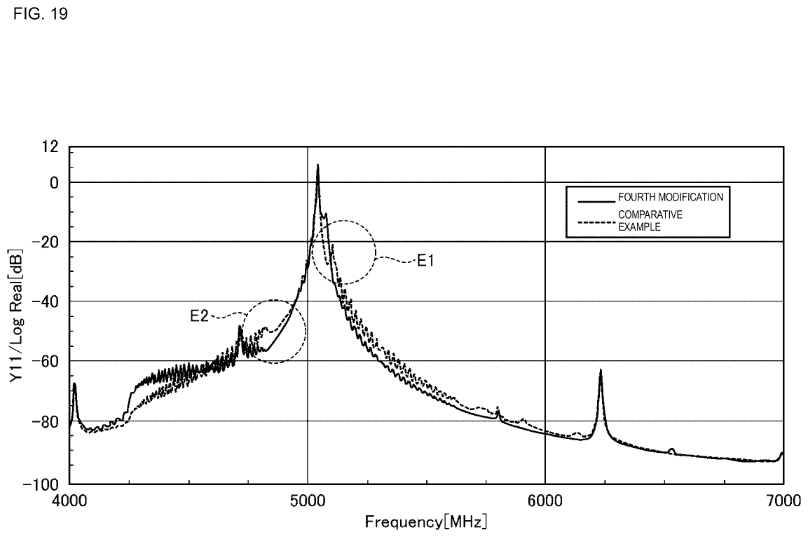

FIG. 19 illustrates an example of the admittance characteristic of the acoustic wave device according to the fourth modification of the first example embodiment. As illustrated in FIG. 19, although the film thicknesses t1 and t2 of the first protective film 41 and the second protective film 42 are small, and the height H1 of the first electrode finger 31a located at the outermost position in the arrangement direction is large, at least the ripple indicated by the dotted line E2 is reduced or prevented in the acoustic wave device 10B described in the fourth modification compared to the comparative example, thus reducing or preventing propagation loss.

The electrode configuration of the IDT electrode 30 described in the fourth modification may be combined with the first modification or the second modification. The height H1 of each of the first electrode finger 31a and the second electrode finger 32a may be greater than the height Hc of the other electrode fingers 31 and 32 (the central electrode fingers 31 and 32). Alternatively, the height H1 of the second electrode finger 32a, located at the second outermost position in the arrangement direction, may be greater than the height Hc of each of the other electrode fingers 31 and 32 (the first electrode finger 31a and the central electrode fingers 31 and 32).

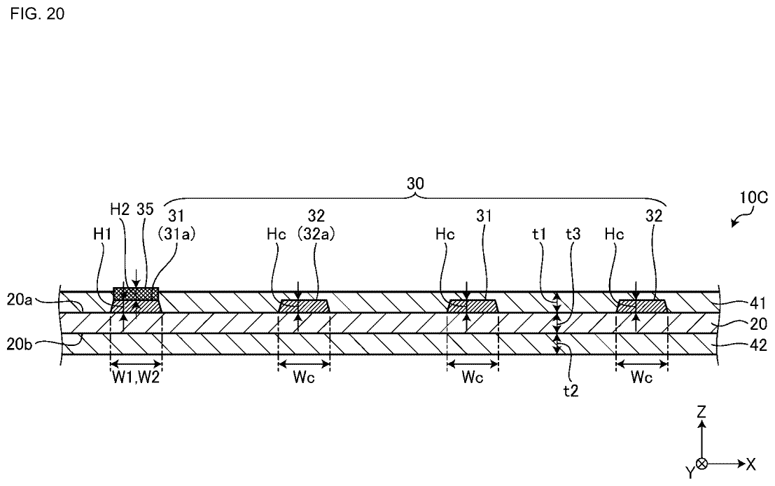

FIG. 20 is a sectional view illustrating an acoustic wave device according to a second example embodiment of the present invention. As illustrated in FIG. 20, an acoustic wave device 10C according to the second example embodiment includes an additional electrode 35. The additional electrode 35 is provided in a region overlying at least one of the first electrode finger 31a or the second electrode finger 32a, which are located at the outermost position among multiple electrode fingers 31 and 32 in the arrangement direction of the multiple electrode fingers 31 and 32. In the second example embodiment, the additional electrode 35 is provided in direct contact with the first electrode finger 31a located at the outermost position in the arrangement direction. In the second example embodiment, the additional electrode 35 is not provided on the second electrode finger 32a located at the second outermost position in the arrangement direction.

The first electrode finger 31a is a monolithic film stack including titanium/aluminum-copper alloy/titanium/aluminum-copper alloy layers. The respective film thicknesses are, for example, about 12 nm/about 70 nm/about 18 nm/about 12 nm. The height H1 (total film thickness) of the first electrode finger 31a is, for example, about 112 nm. The additional electrode 35 is made of an aluminum-copper alloy, and the height H2 (film thickness) of the additional electrode 35 is, for example, about 110 nm. The height of the monolithic film stack of the first electrode finger 31a and the additional electrode 35 (total of the height H1 and the height H2) is, for example, about 222 nm.

The width W2 of the additional electrode 35 is equal or substantially equal to the width W1 of the first electrode finger 31a, both being about 0.6 μm, for example. The density d2 of the additional electrode 35 (aluminum-copper alloy) is equal or substantially equal to the density of a portion of the first electrode finger 31a (aluminum-copper alloy).

Each of the other electrode fingers 31 and 32 (the second electrode finger 32a and the central electrode fingers 31 and 32) is a monolithic film stack including titanium/aluminum-copper alloy/titanium/aluminum-copper alloy layers as described above. The respective film thicknesses are, for example, about 12 nm/about 70 nm/about 18 nm/about 12 nm. The height Hc (total film thickness) of each of the other electrode fingers 31 and 32 is, for example, about 112 nm.

In the present example embodiment, the sum (Xe1+Xe2) of the product Xe1 of the width W1, height H1, and density d1 of the first electrode finger 31a and the product Xe2 of the width W2, height H2, and density d2 of the additional electrode 35 is greater than the product Xc of the width Wc, height Hc, and density dc of the other electrode fingers (the second electrode finger 32a and the central electrode fingers 31 and 32) among the multiple electrode fingers 31 and 32.

The sum (Xe1+Xe2) of the product Xe1 (=W1×H1×d1) of the first electrode finger 31a and the product Xe2 (=W2×H2×d2) of the additional electrode 35 is, for example, Xe1+Xe2=0.6 (μm) ×0.03 (μm)×4500 (kg/m³)+0.6 (μm)×0.192 (μm)×2695 (kg/m³)=391.464. The product Xc (=Wc×Hc×dc) of the other electrode fingers 31 and 32 is Xc=0.6 (μm)×0.03 (μm)×4500 (kg/m³)+0.6 (μm)×0.082 (μm)×2695 (kg/m³)=213.594.

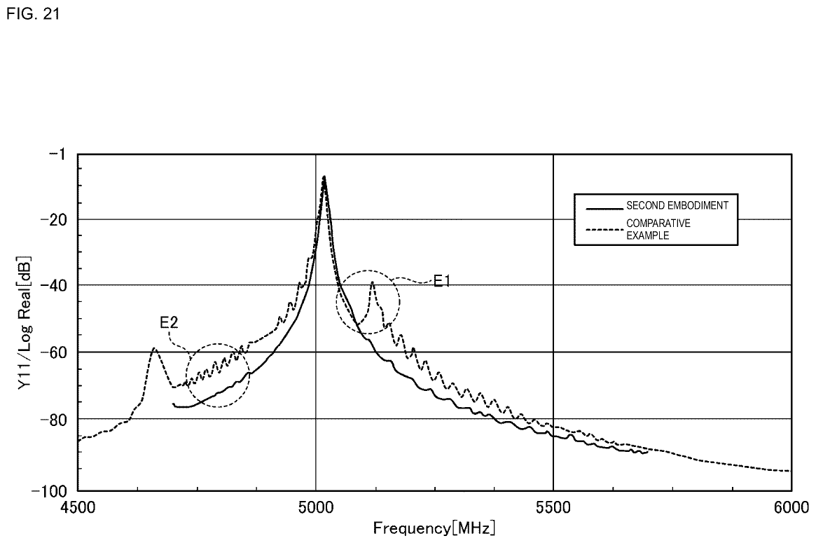

FIG. 21 illustrates an example of the admittance characteristic of the acoustic wave device according to the second example embodiment. The comparative example illustrated in FIG. 21 is an acoustic wave device configured in the same or substantially the same manner as the acoustic wave device 10C described in the second example embodiment, except that the additional electrode 35 is not incorporated.

As illustrated in FIG. 21, since the additional electrode 35 is provided in the acoustic wave device 10C according to the second example embodiment on the first electrode finger 31a located at the outermost position in the arrangement direction, at least the ripple indicated by the dotted line E1 is reduced or prevented compared to the comparative example. In addition, the propagation loss in the frequency range indicated by the dotted line E2 is reduced or prevented in the acoustic wave device 10C described in the second example embodiment.

In the second example embodiment, the additional electrode 35 is provided on the first electrode finger 31a located at the outermost position in the arrangement direction. However, this should not be interpreted as limiting. For example, multiple additional electrodes 35 may be incorporated, and the respective additional electrodes 35 may be provided for the first electrode finger 31a and the second electrode finger 32a. Alternatively, the additional electrode 35 may be provided not on the first electrode finger 31a located at the outermost position in the arrangement direction, but on the second electrode finger 32a adjacent to the first electrode finger 31a.

In FIG. 20, the additional electrode 35 protrudes from the upper surface of the first protective film 41. However, this should not be interpreted as limiting. The first protective film 41 may cover the additional electrode 35. The film thickness t1 of the first protective film 41 may be greater than the height of the monolithic film stacks of the first electrode finger 31a and the additional electrode 35 (total of the height H1 and the height H2). The materials of the additional electrode 35 are not limited to aluminum-copper alloys. As the materials of the additional electrode 35, for example, at least one of tungsten, molybdenum, ruthenium, platinum, copper, silver, chromium, gold, titanium, or aluminum may be used.

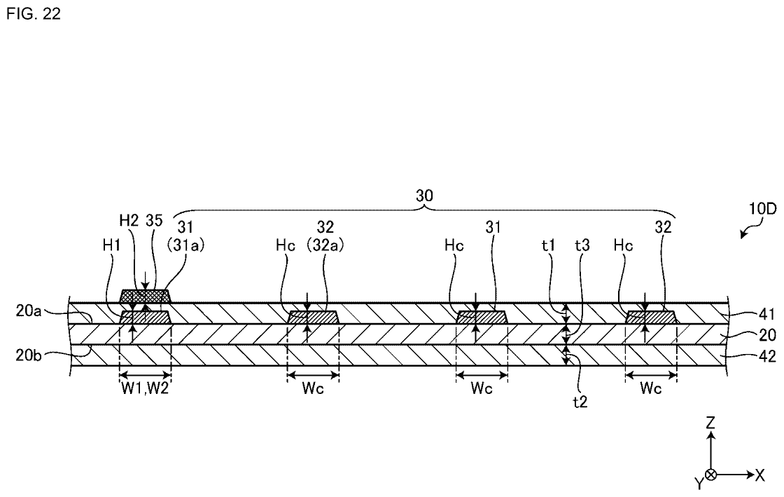

FIG. 22 is a sectional view illustrating an acoustic wave device according to a fifth modification of the second example embodiment. As illustrated in FIG. 22, in an acoustic wave device 10D according to the fifth modification, the additional electrode 35 is provided on the first protective film 41 in the region overlying the first electrode finger 31a located at the outermost position in the arrangement direction. In other words, the first protective film 41 is provided between the first electrode finger 31a and the additional electrode 35 in the direction perpendicular or substantially perpendicular to the first major surface 20a of the piezoelectric layer 20. The first electrode finger 31a and the additional electrode 35 are electrically isolated from each other by the first protective film 41. The upper surface of the first protective film 41 is flat throughout both the region overlying the electrode fingers 31 and 32 and the region not overlying the electrode fingers 31 and 32. The additional electrode 35 protrudes from the upper surface of the first protective film 41.

In the fifth modification, the electrode configuration and materials of the first electrode finger 31a and the additional electrode 35 are the same or substantially the same as in the fourth modification described above. Although the first electrode finger 31a and the additional electrode 35 are spaced apart from each other, the sum (Xe1+Xe2) of the product Xe1 (=W1×H1×d1) of the first electrode finger 31a and the product Xe2 (=W2×H2×d2) of the additional electrode 35 is greater than the product Xc (=Wc×Hc×dc) of the other electrode fingers (the second electrode finger 32a and the central electrode fingers 31 and 32) among multiple electrode fingers 31 and 32.

In the fifth modification, the additional electrode 35 is provided on the first protective film 41 in the region overlying the first electrode finger 31a located at the outermost position in the arrangement direction. However, this should not be interpreted as limiting. For example, multiple additional electrodes 35 may be incorporated, and the additional electrodes 35 may be provided on the first protective film 41 in both regions overlying the first electrode finger 31a and the second electrode finger 32a. Alternatively, the additional electrode 35 may be provided on the first protective film 41 not in the region overlying the first electrode finger 31a located at the outermost position in the arrangement direction, but in the region overlying the second electrode finger 32a adjacent to the first electrode finger 31a.

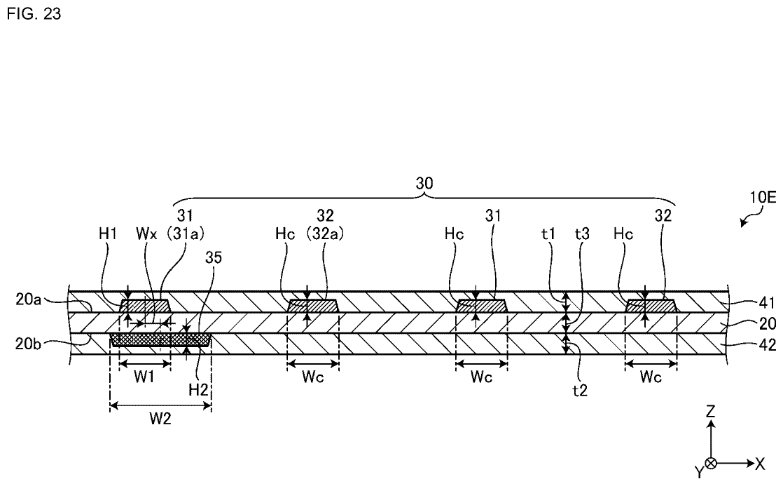

FIG. 23 is a sectional view illustrating an acoustic wave device according to a sixth modification of the second example embodiment. As illustrated in FIG. 23, in an acoustic wave device 10E according to the sixth modification, the additional electrode 35 is provided on the second major surface 20b of the piezoelectric layer 20 in the region overlying (lying under) the first electrode finger 31a located at the outermost position in the arrangement direction. The second protective film 42 is provided on the second major surface 20b of the piezoelectric layer 20 to cover the additional electrode 35. The additional electrode 35 is not provided on the first major surface 20a side of the piezoelectric layer 20. The upper surface of the first protective film 41 is flat.

The first electrode finger 31a is a monolithic film stack including titanium/aluminum-copper alloy/titanium/aluminum-copper alloy layers. The respective film thicknesses are, for example, about 12 nm/about 70 nm/about 18 nm/about 12 nm. The height H1 (total film thickness) of the first electrode finger 31a is, for example, about 112 nm. The additional electrode 35 is a monolithic film stack including titanium/aluminum-copper alloy/titanium/aluminum-copper alloy layers stacked in this order, starting from the side facing the second major surface 20b of the piezoelectric layer 20. The respective film thicknesses are, for example, about 12 nm/about 70 nm/about 18 nm/about 12 nm. The height H2 (film thickness) of the additional electrode 35 is, for example, about 112 nm.

The width W2 of the additional electrode 35 is greater than the width W1 of the first electrode finger 31a. The width W1 of the first electrode finger 31a is, for example, about 0.6 μm. The width W2 of the additional electrode 35 is, for example, about 1.2 μm. The displacement Wx between the center (electrode center) of the first electrode finger 31a in the width direction and the center (electrode center) of the additional electrode 35 in the width direction is, for example, about 0.2 μm. The density d2 of the additional electrode 35 is equal or substantially equal to the density d1 of the first electrode finger 31a.

The electrode configuration (width Wc, height Hc, density dc) of the other electrode fingers 31 and 32 (the second electrode finger 32a and the central electrode fingers 31 and 32) is the same or substantially the same as the first electrode finger 31a.

In the sixth modification, although the first electrode finger 31a is provided on the first major surface 20a of the piezoelectric layer 20, while the additional electrode 35 is provided on the second major surface 20b of the piezoelectric layer 20, the sum (Xe1+Xe2) of the product Xe1 (=W1×H1×d1) of the first electrode finger 31a and the product Xe2 (=W2×H2×d2) of the additional electrode 35 is greater than the product Xc (=Wc×Hc×dc) of the other electrode fingers (the second electrode finger 32a and the central electrode fingers 31 and 32) among multiple electrode fingers 31 and 32.

The sum (Xe1+Xe2) of the product Xe1 (=W1×H1×d1) of the first electrode finger 31a and the product Xe2 (=W2×H2×d2) of the additional electrode 35 is, for example, Xe1+Xe2=0.6 (μm) ×0.03 (μm)×4500 (kg/m³)+0.6 (μm)×0.082 (μm)×2695 (kg/m³)+1.2 (μm)×0.03 (μm)×4500 (kg/m³)+1.2 (μm)×0.082 (μm)×2695 (kg/m³)=640.782. The product Xc (=Wc×Hc×dc) of the other electrode fingers 31 and 32 is, for example, Xc=0.6 (μm)×0.03 (μm)×4500 (kg/m³)+0.6 (μm)×0.082 (μm)×2695 (kg/m³)=213.594.

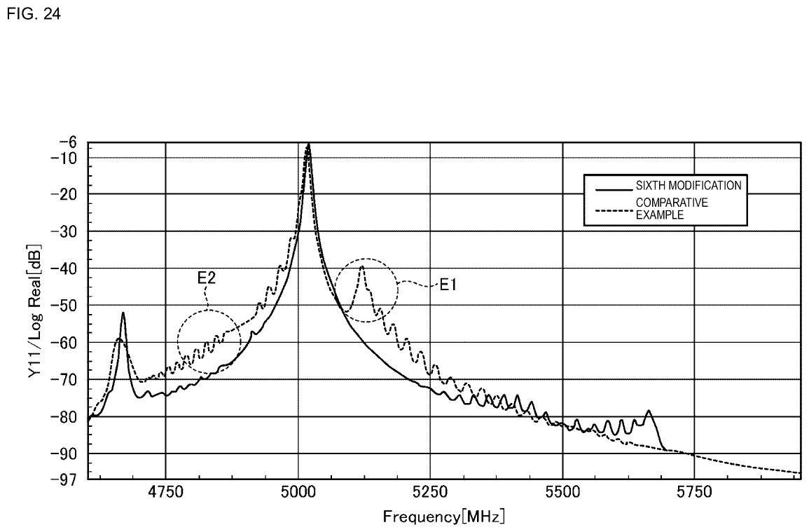

FIG. 24 illustrates an example of the admittance characteristic of the acoustic wave device according to the sixth modification of the second example embodiment. As illustrated in FIG. 24, in the acoustic wave device 10E according to the sixth modification, with the additional electrode 35 provided on the second major surface 20b of the piezoelectric layer 20, at least the ripple indicated by the dotted line E1 is reduced or prevented compared to the comparative example. In addition, the propagation loss in the frequency range indicated by the dotted line E2 is reduced or prevented in the acoustic wave device 10E according to the sixth modification. In the present modification, since the upper surface of the first protective film 41 is flat, the resonant frequency can be easily controlled by changing the film thickness of the first protective film 41.

In the sixth modification, the additional electrode 35 is provided on the second major surface 20b of the piezoelectric layer 20 in the region overlying the first electrode finger 31a located at the outermost position in the arrangement direction. However, this should not be interpreted as limiting. For example, multiple additional electrodes 35 may be incorporated, and the additional electrodes 35 may be provided on the second major surface 20b of the piezoelectric layer 20 in both regions overlying the first electrode finger 31a and the second electrode finger 32a. Alternatively, the additional electrode 35 may be provided on the second major surface 20b of the piezoelectric layer 20 not in the region overlying the first electrode finger 31a located at the outermost position in the arrangement direction, but in the region overlying the second electrode finger 32a adjacent to the first electrode finger 31a.

Features such as the electrode configuration (width W2, height H2, density d2) of the additional electrode 35 and the displacement Wx with respect to the first electrode finger 31a are merely illustrative and may be modified as needed. For example, the configuration is not limited to a configuration in which the width W2 of the additional electrode 35 is greater than the width W1 of the first electrode finger 31a. The width W2, height H2, and density d2 of the additional electrode 35 may be equal or substantially equal to the width W1, height H1, and density d1 of the first electrode finger 31a. Alternatively, the displacement Wx between the additional electrode 35 and the first electrode finger 31a may be 0 (zero). The additional electrode 35 is not limited to a monolithic film stack but may be a multilayer film stack. Alternatively, the additional electrode 35 may be made of materials having densities different from the densities of materials of the first electrode finger 31a.

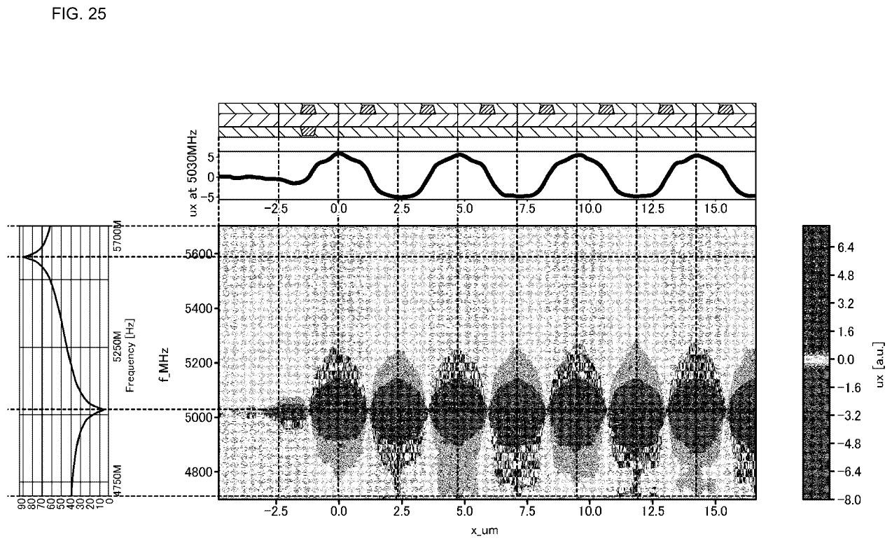

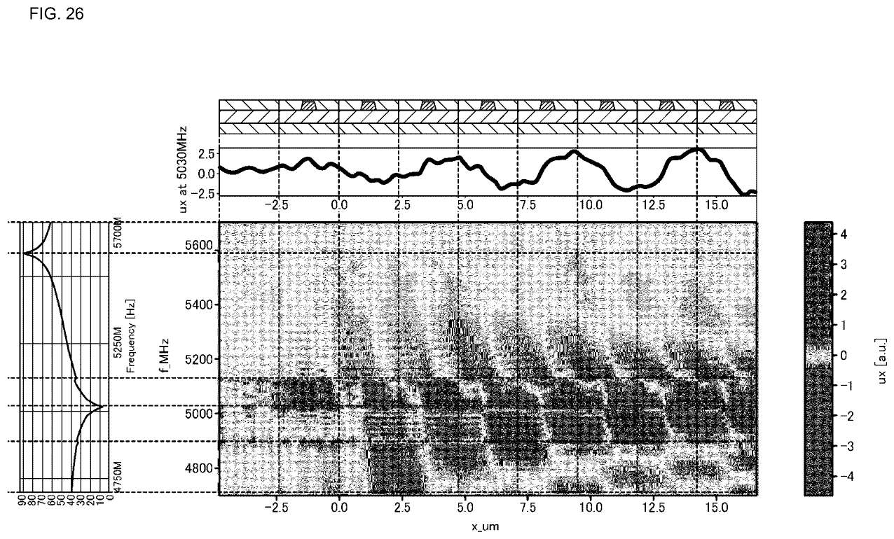

FIG. 25 illustrates the vibration mode distribution of the acoustic wave device according to the sixth modification of the second example embodiment. FIG. 26 illustrates the vibration mode distribution of an acoustic wave device according to a comparative example. The comparative example illustrated in FIG. 26 is configured in the same or substantially the same manner as the acoustic wave device 10E according to the sixth modification, except that the additional electrode 35 is not included.

FIGS. 25 and 26 illustrate the distribution of displacement magnitude in the piezoelectric layer 20 for the sixth modification and the comparative example, where the horizontal axis represents the X direction (the arrangement direction of the electrode fingers 31 and 32) and the vertical axis represents frequency. The upper portions of FIGS. 25 and 26 illustrate schematic sectional views of the acoustic wave devices along the X direction, while the left portions of FIGS. 25 and 26 illustrate the impedance characteristics of the respective acoustic wave devices.

As illustrated in FIG. 26, the X-directional dependence of displacement (the X-directional positions of antinodes and nodes of displacement) in the acoustic wave device according to the comparative example is strongly dependent on frequency. For example, the X-directional positions of the displacement peaks vary with frequencies, and the excitation is unstable between the electrodes. Focusing on a specific X position (near X=about 5.0 μm), the phase is inverted at the resonant frequency of about 5030 MHz, and at the frequencies of about 4900 MHz and about 5120 MHz, at which ripples occur. As described above, ideal excitation modes cannot be obtained for the acoustic wave device according to the comparative example.

In contrast, as illustrated in FIG. 25, the X-directional dependence of displacement (the X-directional positions of antinodes and nodes of displacement) in the acoustic wave device 10E according to the sixth modification is independent of frequency. This means that the X-directional positions of the displacement peaks remain constant regardless of frequency, indicating that stable excitation is maintained between the electrodes. The displacement magnitude (amplitude) also remains constant throughout the regions between the electrodes, and no phase inversion occurs at the resonant frequency or at a set of frequencies at which ripples occur. As described above, providing the additional electrode 35 in the region overlying the first electrode finger 31a, which is located at the outermost position in the arrangement direction, yields a more favorable excitation mode than in the comparative example.

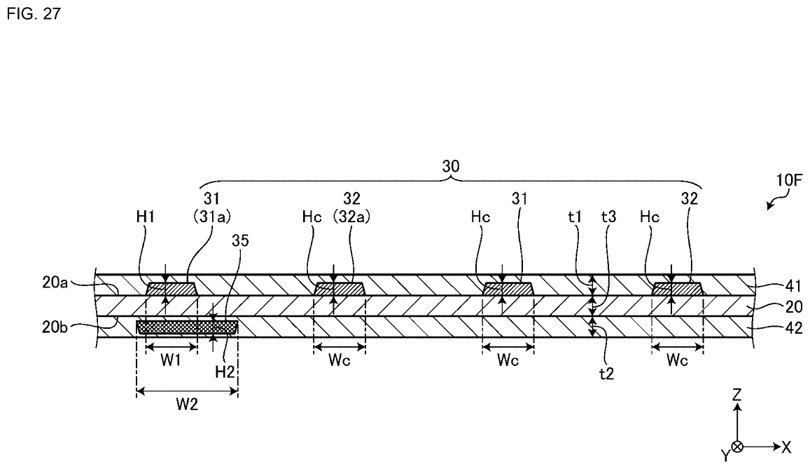

FIG. 27 is a sectional view illustrating an acoustic wave device according to a seventh modification of the second example embodiment. As illustrated in FIG. 27, in an acoustic wave device 10F according to the seventh modification, the additional electrode 35 is provided on the side facing the second major surface 20b of the piezoelectric layer 20 in the region overlying the first electrode finger 31a located at the outermost position in the arrangement direction. More specifically, the additional electrode 35 is provided to face the second major surface 20b of the piezoelectric layer 20 and is spaced away from the second major surface 20b.

The additional electrode 35 is disposed within the second protective film 42. Specifically, the second protective film 42 is provided between the second major surface 20b of the piezoelectric layer 20 and the additional electrode 35 and covers the side surfaces and the lower surface (the opposite surface to the piezoelectric layer 20) of the additional electrode 35.

In the seventh modification, the electrode configuration of the first electrode finger 31a and the additional electrode 35 may be the same or substantially the same as in the sixth modification. Specifically, in the seventh modification, the sum (Xe1+Xe2) of the product Xe1 (=W1×H1×d1) of the first electrode finger 31a and the product Xe2 (=W2×H2×d2) of the additional electrode 35 is greater than the product Xc (=Wc×Hc×dc) of the other electrode fingers (the second electrode finger 32a and the central electrode fingers 31 and 32) among multiple electrode fingers 31 and 32.

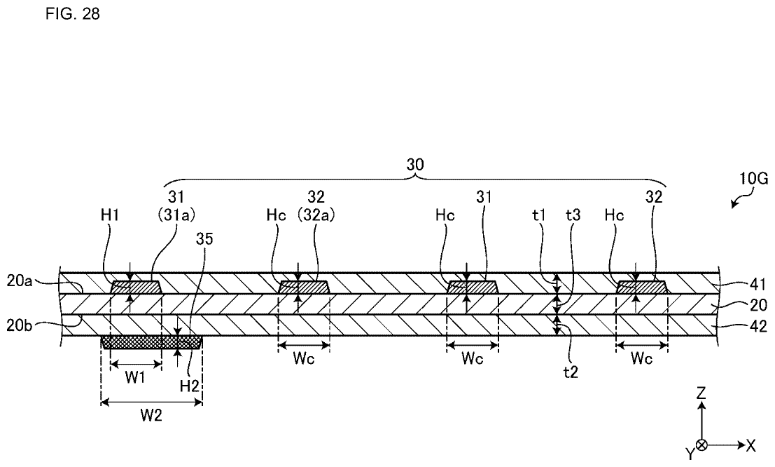

FIG. 28 is a sectional view illustrating an acoustic wave device according to an eighth modification of the second example embodiment. As illustrated in FIG. 28, in an acoustic wave device 10G according to the eighth modification, the additional electrode 35 is provided on the lower surface of the second protective film 42 in the region overlying the first electrode finger 31a located at the outermost position in the arrangement direction. The lower surface of the second protective film 42 is flat, lying along the second major surface 20b of the piezoelectric layer 20. The additional electrode 35 protrudes from the lower surface of the second protective film 42. The lower surface of the second protective film 42 is the surface of the second protective film 42 that faces the support substrate 11 (see FIG. 2).

In the eighth modification, the electrode configuration of the first electrode finger 31a and the additional electrode 35 may be the same or substantially the same as in the sixth or seventh modification. Specifically, in the eighth modification, the sum (Xe1+Xe2) of the product Xe1 (=W1×H1×d1) of the first electrode finger 31a and the product Xe2 (=W2×H2×d2) of the additional electrode 35 is greater than the product Xc (=Wc×Hc×dc) of the other electrode fingers (the second electrode finger 32a and the central electrode fingers 31 and 32) among multiple electrode fingers 31 and 32.

In the seventh and eighth modifications, the additional electrode 35 is provided in the region overlying the first electrode finger 31a located at the outermost position in the arrangement direction. However, this should not be interpreted as limiting. For example, multiple additional electrodes 35 may be incorporated, and the additional electrodes 35 may be provided within the second protective film 42 or on the lower surface of the second protective film 42 in both regions overlying the first electrode finger 31a and the second electrode finger 32a. Alternatively, the additional electrode 35 may be provided within the second protective film 42 or on the lower surface of the second protective film 42 not in the region overlying the first electrode finger 31a located at the outermost position in the arrangement direction, but in the region overlying the second electrode finger 32a adjacent to the first electrode finger 31a.

In the seventh and eighth modifications, features such as the electrode configuration (width W2, height H2, density d2) of the additional electrode 35 and the displacement Wx with respect to the first electrode finger 31a are merely illustrative and may be modified as needed. For example, the configuration is not limited to a configuration in which the width W2 of the additional electrode 35 is greater than the width W1 of the first electrode finger 31a. The width W2, height H2, and density d2 of the additional electrode 35 may be equal or substantially equal to the width W1, height H1, and density d1 of the first electrode finger 31a. Alternatively, the additional electrode 35 is not limited to a monolithic film stack but may be a multilayer film stack. Alternatively, the additional electrode 35 may be made of materials having densities different from the densities of materials of the first electrode finger 31a.

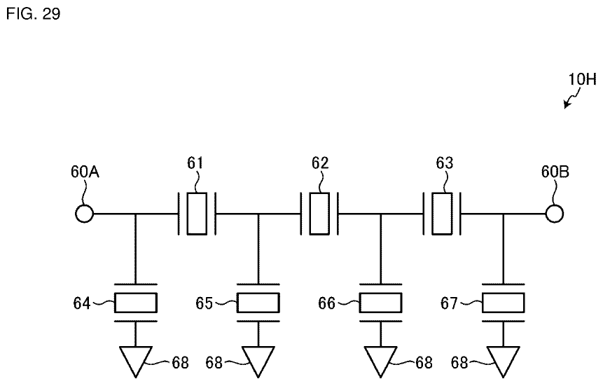

FIG. 29 is a circuit diagram of an acoustic wave device according to a third example embodiment of the present invention. As illustrated in FIG. 29, an acoustic wave device 10H according to the third example embodiment includes multiple series arm resonators 61, 62, and 63 and multiple parallel arm resonators 64, 65, 66, and 67. The series arm resonators 61, 62, and 63 are coupled in series in the signal path between an input terminal 60A and an output terminal 60B. The parallel arm resonators 64, 65, 66, and 67 are coupled in parallel between ground 68 and the signal path between the input terminal 60A and the output terminal 60B. The acoustic wave device 10H according to the third example embodiment is a ladder filter.

One terminal of each of the series arm resonators 61, 62, and 63, which are coupled in series, is electrically coupled to the input terminal 60A, and the other terminal is electrically coupled to the output terminal 60B. One terminal of the parallel arm resonator 64 is electrically coupled to the input terminal 60A, and the other terminal is electrically coupled to the ground 68. One terminal of the parallel arm resonator 65 is electrically coupled to the signal path connecting the series arm resonator 61 and the series arm resonator 62, and the other terminal is electrically coupled to the ground 68. One terminal of the parallel arm resonator 66 is electrically coupled to the signal path connecting the series arm resonator 62 and the series arm resonator 63, and the other terminal is electrically coupled to the ground 68. One terminal of the parallel arm resonator 67 is electrically coupled to the output terminal 60B, and the other terminal is electrically coupled to the ground 68.

In the present example embodiment, the first electrode finger 31a and the second electrode finger 32a, which are located on the outer side in the arrangement direction, have different electrode configurations by using the series arm resonators 61, 62, and 63 and the parallel arm resonators 64, 65, 66, and 67. For example, the series arm resonators 61, 62, and 63 include the first electrode finger 31a illustrated in the first example embodiment (see FIGS. 12 and 13). The admittance characteristics of the series arm resonators 61, 62, and 63 are the same or substantially the same as in FIG. 13, and descriptions thereof will not be repeated.

On the other hand, the parallel arm resonators 64, 65, 66, and 67 include the first electrode finger 31a and the additional electrode 35 described in the second example embodiment (see FIGS. 20 and 21). The admittance characteristics of the parallel arm resonators 64, 65, 66, and 67 are the same or substantially the same as in FIG. 21, and descriptions thereof will not be repeated.

In the present example embodiment, providing different configurations among the first electrode finger 31a and the second electrode finger 32a, and the additional electrode 35 by using the series arm resonators 61, 62, and 63 and the parallel arm resonators 64, 65, 66, and 67 yields a better output waveform as a filter.

In the acoustic wave device 10H according to the third example embodiment, an example has been described regarding the electrode configurations of the first electrode finger 31a and the second electrode finger 32a described in the first example embodiment, the electrode configuration of the additional electrode 35 described in the second example embodiment, and the combination thereof. However, this should not be interpreted as limiting. The third example embodiment may be combined with each of the example embodiments and modifications described above.

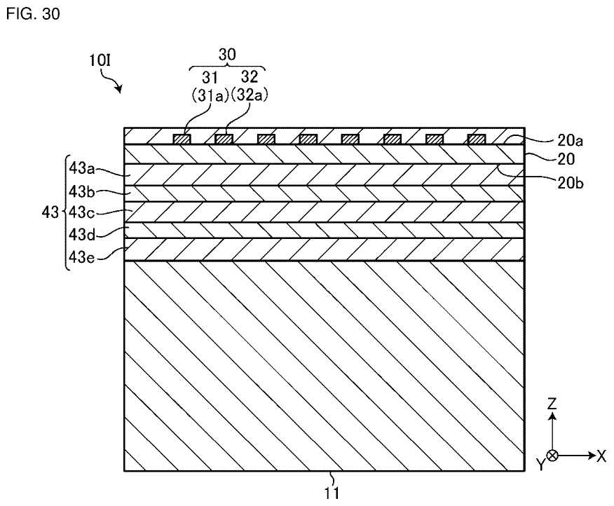

FIG. 30 is a sectional view illustrating an acoustic wave device according to a ninth modification of an example embodiment of the present invention. In the acoustic wave device 10 of the first example embodiment described above, a membrane structure has been described in which the support substrate 11 includes the cavity portion 14, and the cavity portion 14 (hollow portion) is provided on the side facing the second major surface 20b of the piezoelectric layer 20. However, this should not be interpreted as limiting.

As illustrated in FIG. 30, in an acoustic wave device 10I according to the ninth modification, an acoustic multilayer film 43 is disposed on the second major surface 20b of the piezoelectric layer 20. The acoustic multilayer film 43 has a layered structure including low acoustic impedance layers 43a, 43c, and 43e having relatively low acoustic impedance, and high acoustic impedance layers 43b and 43d having relatively high acoustic impedance. The low acoustic impedance layers 43a, 43c, and 43e are, for example, silicon oxide layers, while the high acoustic impedance layers 43b and 43d are, for example, metallic layers of tungsten, platinum, or other material, or dielectric layers of aluminum nitride, silicon nitride, or other material. When the acoustic multilayer film 43 is used, the bulk wave of the first thickness-shear mode can be confined within the piezoelectric layer 20 without using the cavity portion 14.

In the acoustic wave device 10I as well, the resonance characteristic based on the bulk wave of the first thickness-shear mode can be obtained by setting d/p described above to, for example, less than or equal to about 0.5. In the acoustic multilayer film 43, the numbers of the low acoustic impedance layers 43a, 43c, and 43e and the high acoustic impedance layers 43b and 43d are not limited to any particular numbers. It is sufficient that at least one of the high acoustic impedance layer 43b or 43d is disposed farther from the piezoelectric layer 20 than the low acoustic impedance layers 43a, 43c, and 43e.

The low acoustic impedance layers 43a, 43c, and 43e and the high acoustic impedance layers 43b and 43d may be made of any suitable materials when the materials satisfy the acoustic impedance relationship described above. Examples of materials for the low acoustic impedance layers 43a, 43c, and 43e include silicon oxide or silicon oxynitride. Examples of materials for the high acoustic impedance layers 43b and 43d include alumina, silicon nitride, or metal.

FIG. 30 may be combined with the electrode configuration of the first electrode finger 31a described in the first example embodiment. However, this should not be interpreted as limiting. The ninth modification may be combined with each of the example embodiments and modifications described above.

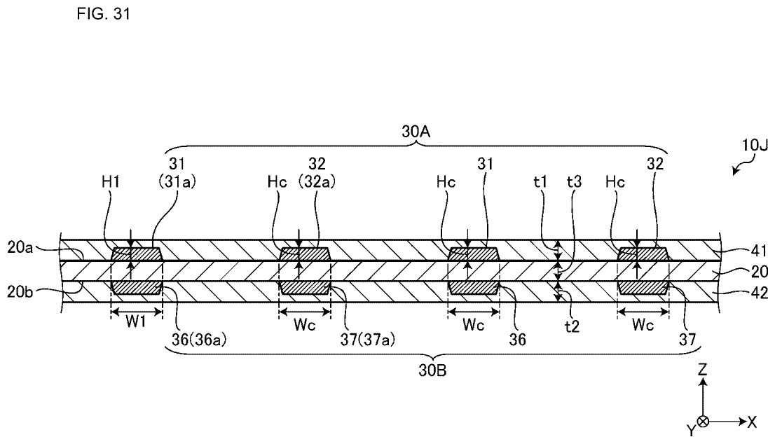

FIG. 31 is a sectional view illustrating an acoustic wave device according to a tenth modification of an example embodiment of the present invention. It has been described that, in the acoustic wave device 10 of the first example embodiment, the IDT electrode 30 is disposed on the first major surface 20a of the piezoelectric layer 20. However, this should not be interpreted as limiting. As illustrated in FIG. 31, an acoustic wave device 10J according to the tenth modification includes a first IDT electrode 30A disposed on the first major surface 20a of the piezoelectric layer 20 and a second IDT electrode 30B disposed on the second major surface 20b of the piezoelectric layer 20. The first IDT electrode 30A and the second IDT electrode 30B have the same or substantially the same configuration as the IDT electrode 30 (see FIGS. 1 and 2).

Electrode fingers 36 and 37 of the second IDT electrode 30B are disposed in the regions overlying the electrode fingers 31 and 32 of the first IDT electrode 30A. The electrode fingers 36 and 37 of the second IDT electrode 30B have the same or substantially the same widths as the widths of the electrode fingers 31 and 32 of the first IDT electrode 30A and are disposed with the same or substantially the same inter-electrode pitch. In the tenth modification, as in the first example embodiment, at least one of the first electrode finger 31a or the second electrode finger 32a of the first IDT electrode 30A is made of a material having a higher density than the other central electrode fingers 31 and 32. At least one of the first electrode finger 36a or the second electrode finger 37a of the second IDT electrode 30B is made of a material having a higher density than the other central electrode fingers 36 and 37.

In the tenth modification, the first IDT electrode 30A and the second IDT electrode 30B are respectively provided on the first major surface 20a and the second major surface 20b of the piezoelectric layer 20. This configuration improves the temperature coefficients of frequency (TCF).

The tenth modification may be combined with each of the example embodiments and modifications described above. For example, in the tenth modification, an additional electrode 35 may be provided on at least one of the side facing the first major surface 20a or the side facing the second major surface 20b of the piezoelectric layer 20.

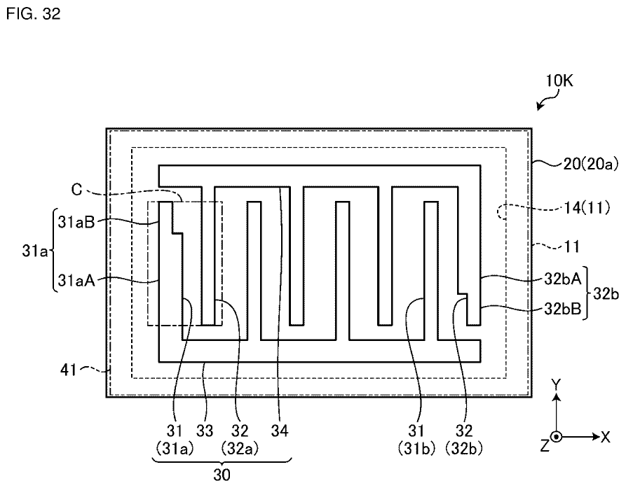

FIG. 32 is a plan view illustrating an acoustic wave device according to an eleventh modification of an example embodiment of the present invention. An acoustic wave device 10K according to the eleventh modification differs from the first example embodiment described above in that the product Xe (=W1×H1×d1) of the width W1, the height H1, and the density d1 of at least a portion of the first electrode finger 31a in the extension direction is greater than the product Xc (=Wc×Hc×dc) of the width Wc, the height Hc, and the density dc of the central electrode fingers 31 and 32 other than the first electrode finger 31a and the second electrode finger 32a among the multiple electrode fingers 31 and 32. In this case as well, as in the first example embodiment, ripples in the admittance characteristic can be reduced or prevented as compared to the comparative example.

More specifically, the first electrode finger 31a includes a first portion 31aA and a second portion 31aB. The second portion 31aB is connected to an end portion of the first portion 31aA in the extension direction.

The product Xe (=W1×H1×d1) of the width W1, the height H1, and the density d1 of the first portion 31aA of the first electrode finger 31a is greater than the product Xc (=Wc×Hc×dc) of the width Wc, the height Hc, and the density dc of the central electrode fingers 31 and 32 other than the first electrode finger 31a and the second electrode finger 32a among the multiple electrode fingers 31 and 32.

The width W1 of the second portion 31aB is smaller than the width W1 of the first portion 31aA. The product Xe (=W1×H1×d1) of the width W1, the height H1, and the density d1 of the second portion 31aB is smaller than the product Xe (=W1×H1×d1) of the width W1, the height H1, and the density d1 of the first portion 31aA.

Similarly, the fourth electrode finger 32b, which is located on the opposite side from the first electrode finger 31a among the multiple electrode fingers 31 and 32 in the arrangement direction of the multiple electrode fingers 31 and 32, includes a first portion 32bA and a second portion 32bB. The product Xe (=W1 ×H1×d1) of the width W1, the height H1, and the density d1 of at least a portion (the first portion 32bA) of the fourth electrode finger 32b in the extension direction is greater than the product Xc (=Wc×Hc×dc) of the width Wc, the height Hc, and the density dc of the central electrode fingers 31 and 32 other than the third electrode finger 31b and the fourth electrode finger 32b among the multiple electrode fingers 31 and 32.

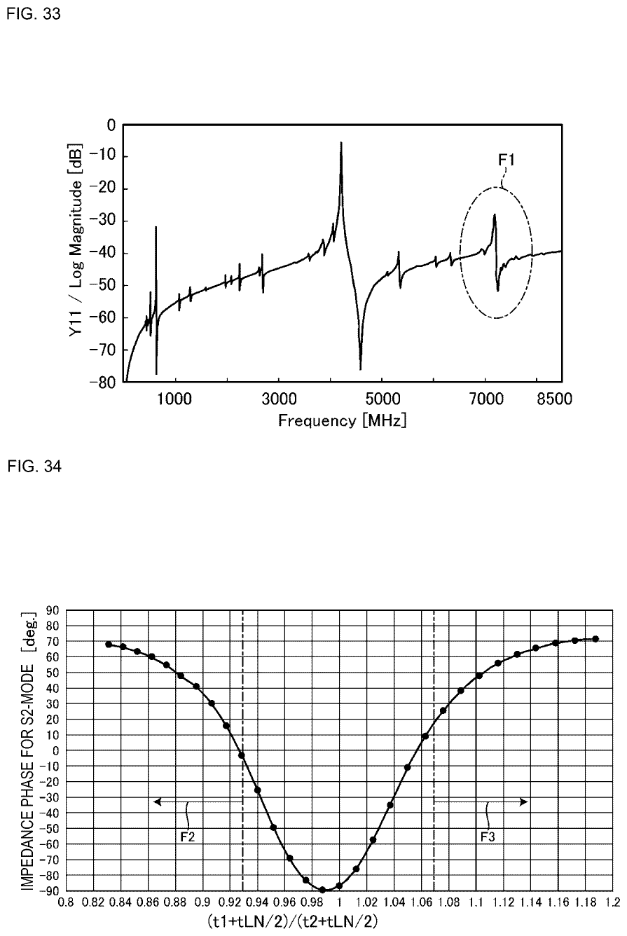

FIG. 33 illustrates an example of the admittance characteristic of an acoustic wave device according to a twelfth modification of an example embodiment of the present invention. FIG. 34 illustrates an example of impedance phase for the S2 mode. The acoustic wave device according to the twelfth modification illustrated in FIG. 33 is used to describe a configuration in which the film thicknesses of the first protective film 41 and the second protective film 42 are varied based on the acoustic wave device 10 of the first example embodiment described above.

FIG. 33 illustrates the frequency characteristic of the absolute value of admittance of the acoustic wave device according to the twelfth modification. As illustrated in FIG. 33, in the acoustic wave device according to the twelfth modification, a higher-order mode resonance occurs in the frequency region indicated by the dot-dash line F1, which includes frequencies different from the resonant frequency (hereinafter referred to as the “S2 mode”).

The horizontal axis of the graph illustrated in FIG. 34 represents the ratio (t1+tLN/2)/(t2+tLN/2), where (t1+tLN/2) is the sum of the film thickness t1 of the first protective film 41 and ½ of the film thickness tLN of the piezoelectric layer 20, and (t2+tLN/2) is the sum of the film thickness t2 of the second protective film 42 and ½ of the film thickness tLN of the piezoelectric layer 20. The vertical axis of the graph illustrated in FIG. 34 represents the intensity of the S2 mode.

In FIG. 34, the ranges indicated by the arrows F2 and F3 correspond to the ratio (t1+tLN/2)/(t2+tLN/2) in the configuration of the acoustic resonator device described in Japanese Unexamined Patent Application Publication No. 2022-524136. In the acoustic resonator device described in Japanese Unexamined Patent Application Publication No. 2022-524136, the ratio (t1+tLN/2)/(t2+tLN/2) is less than or equal to 0.93 or greater than or equal to 1.07, indicating that the intensity of the S2 mode is high.

In contrast, in the twelfth modification, the ratio (t1 +tLN/2)/(t2+tLN/2) is within the range from about 0.94 to about 1.06 inclusive, indicating that the intensity of the S2 mode is smaller than in the acoustic resonator device described in Japanese Unexamined Patent Application Publication No. 2022-524136. Accordingly, when the total distance from the center of the film thickness of the piezoelectric layer 20 to the top surface of the first protective film 41 is defined as A, and the total distance from the center of the film thickness of the piezoelectric layer 20 to the top surface of the second protective film 42 is defined as B, the value of A/B is, for example, preferably within the range from about 1−0.06 to about 1+0.06 inclusive.

In the twelfth modification, it has been described that the film thicknesses of the first protective film 41 and the second protective film 42 are varied based on the acoustic wave device 10 of the first example embodiment. However, this should not be interpreted as limiting. The relationship between the film thickness t1 of the first protective film 41, the film thickness tLN of the piezoelectric layer 20, and the film thickness t2 of the second protective film 42 in the twelfth modification may be combined with each of the example embodiments and modifications described above.

The example embodiments described above have been provided for ease of understanding the present invention and should not be interpreted as limiting the present invention. The present invention may be changed or improved without departing from scope and spirit of the present invention, and the present invention also includes equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first major surface and a second major surface opposite the first major surface in a first direction;
an interdigital transducer (IDT) electrode on at least one of the first major surface or the second major surface of the piezoelectric layer, and including a plurality of electrode fingers arranged in an arrangement direction; and
a support facing the second major surface of the piezoelectric layer, and including an acoustic reflection portion on a side facing the second major surface of the piezoelectric layer; wherein
the plurality of electrode fingers include a first electrode finger located at an outermost position in the arrangement direction and a second electrode finger adjacent to the first electrode finger;
a product of a width, a height, and a density of at least one of the first electrode finger or the second electrode finger is greater than a product of a width, a height, and a density of a central electrode finger different from the first electrode finger and the second electrode finger among the plurality of electrode fingers; and
when a thickness of the piezoelectric layer is denoted by d and a center-to-center distance between adjacent electrode fingers among the plurality of electrode fingers is denoted by p, d/p is less than or equal to about 0.5.

2. The acoustic wave device according to claim 1, further comprising a protective film on at least one of the first major surface or the second major surface of the piezoelectric layer.

3. The acoustic wave device according to claim 1, wherein at least one of the first electrode finger or the second electrode finger includes a material with a higher density than the central electrode finger.

4. The acoustic wave device according to claim 1, wherein the height of at least one of the first electrode finger or the second electrode finger is greater than the height of the central electrode finger.

5. An acoustic wave device comprising:
a piezoelectric layer including a first major surface and a second major surface opposite the first major surface in a first direction;
an interdigital transducer (IDT) electrode on at least one of the first major surface or the second major surface of the piezoelectric layer, and including a plurality of electrode fingers arranged in an arrangement direction;
a support facing the second major surface of the piezoelectric layer, and including an acoustic reflection portion on a side facing the second major surface of the piezoelectric layer; and
an additional electrode in a region overlying at least one of a first electrode finger or a second electrode finger, the first electrode finger being an electrode finger among the plurality of electrode fingers located at an outermost position in the arrangement direction, and the second electrode finger being an electrode finger adjacent to the first electrode finger among the plurality of electrode fingers; wherein
a sum of a product of a width, a height, and a density of at least one of the first electrode finger or the second electrode finger and a product of a width, a height, and a density of the additional electrode is greater than a product of a width, a height, and a density of a central electrode finger different from the first electrode finger and the second electrode finger among the plurality of electrode fingers; and
when a thickness of the piezoelectric layer is denoted by d and a center-to-center distance between adjacent electrode fingers among the plurality of electrode fingers is denoted by p, d/p is less than or equal to about 0.5.

6. The acoustic wave device according to claim 5, further comprising a protective film on at least one of the first major surface or the second major surface of the piezoelectric layer.

7. The acoustic wave device according to claim 5, wherein the additional electrode is in contact with at least one of the first electrode finger or the second electrode finger.

8. The acoustic wave device according to claim 6, wherein
the protective film includes a first protective film on the first major surface of the piezoelectric layer and covers the IDT electrode; and
the additional electrode is on the first protective film within a region overlying at least one of the first electrode finger or the second electrode finger.

9. The acoustic wave device according to claim 5, wherein the additional electrode is on the second major surface of the piezoelectric layer within a region overlying at least one of the first electrode finger or the second electrode finger.

10. The acoustic wave device according to claim 1, wherein a material of the plurality of electrode fingers of the IDT electrode includes at least one of tungsten, molybdenum, ruthenium, platinum, copper, silver, chromium, gold, titanium, or aluminum.

11. The acoustic wave device according to claim 5, wherein a material of the additional electrode includes at least one of tungsten, molybdenum, ruthenium, platinum, copper, silver, chromium, gold, titanium, or aluminum.

12. The acoustic wave device according to claim 2, wherein a film thickness of the protective film is smaller than a film thickness of the plurality of electrode fingers.

13. The acoustic wave device according to claim 1, wherein the IDT electrode is on both the first major surface and the second major surface of the piezoelectric layer.

14. An acoustic wave filter device comprising:
at least one resonator including the acoustic wave device according to claim 1.

15. The acoustic wave filter device according to claim 14, further comprising:
an input terminal, an output terminal, a series arm coupling the input terminal to the output terminal, and a parallel arm coupling a node of the series arm to ground; wherein
the at least one resonator includes a plurality of resonators including a series arm resonator in the series arm and a parallel arm resonator in the parallel arm; and
a material of at least one of the first electrode finger or the second electrode finger of the series arm resonator differs from a material of at least one of the first electrode finger and the second electrode finger of the parallel arm resonator.

16. An acoustic wave filter device comprising:
at least one resonator including the acoustic wave device according to claim 5.

17. The acoustic wave filter device according to claim 16, further comprising:
an input terminal, an output terminal, a series arm coupling the input terminal to the output terminal, and a parallel arm coupling a node of the series arm to ground; wherein
the at least one resonator includes a plurality of resonators including a series arm resonator in the series arm and a parallel arm resonator in the parallel arm; and
the additional electrode of the series arm resonator is configured in a different manner from the additional electrode of the parallel arm resonator.

18. The acoustic wave device according to claim 2, wherein the protective film includes silicon oxide.

19. The acoustic wave device according to claim 1, wherein the piezoelectric layer includes lithium niobate or lithium tantalate and has a 120°±10° rotated Y-cut or a 90°±10° rotated Y-cut.

20. The acoustic wave device according to claim 2, wherein the protective film includes a first protective film on the first major surface of the piezoelectric layer and covers the IDT electrode and a second protective film on the second major surface of the piezoelectric layer.

21. The acoustic wave device according to claim 2, wherein a film thickness of the protective film is greater than a film thickness of the IDT electrode.

22. The acoustic wave device according to claim 20, wherein, when a total distance from a center of a film thickness of the piezoelectric layer to a top surface of the first protective film is defined as A, and the total distance from the center of the film thickness of the piezoelectric layer to a top surface of the second protective film is defined as B, a value of A/B is within the range from about 1−0.06 to about 1+0.06 inclusive.

23. The acoustic wave device according to claim 20, wherein an upper surface of the first protective film and a lower surface of the second protective film are flat.

24. The acoustic wave device according to a claim 1, wherein d/p is less than or equal to about 0.24.

25. The acoustic wave device according to claim 1, wherein, when viewed in a direction orthogonal or substantially orthogonal to the plurality of electrode fingers, an excitation region corresponds to a region in which adjacent electrode fingers among the plurality of electrode fingers overlap each other, the region being located between centers of the adjacent electrode fingers in the direction orthogonal or substantially orthogonal to the plurality of electrode fingers; and
when a metallization ratio of the plurality of electrode fingers to the excitation region is denoted by MR, MR≤about 1.75 (d/p)+0.075.

26. The acoustic wave device according to claim 1, wherein the piezoelectric layer includes lithium tantalate or lithium niobate.

27. The acoustic wave device according to claim 26, wherein
Euler angles (φ, θ, ψ) of lithium niobate or lithium tantalate of the piezoelectric layer are within any one of the ranges defined by the expressions (1), (2), or (3):
(0°±10°, 0° to 20°, any ψ) . . . Expression (1);
(0°±10°, 20° to 80°, 0° to 60°(1−(θ−50)²/900)^{1/2}) or (0°±10°, 20° to 80°, [180°-60°(1−(θ−50)²/900)^{1/2}] to 180°) . . . Expression (2); or
(0°±10°, [180°-30°(1−(ψ−90)²/8100)^{1/2}] to 180°, any ψ) . . . Expression (3).

28. The acoustic wave device according to claim 1, wherein
the acoustic reflection portion includes a hollow portion; and
the support and the piezoelectric layer are arranged such that a portion of the support and a portion of the piezoelectric layer face each other with the hollow portion interposed between the support and the piezoelectric layer.

29. The acoustic wave device according to claim 1, wherein
the acoustic reflection portion includes an acoustic reflection film including a high acoustic impedance layer having relatively high acoustic impedance and a low acoustic impedance layer having relatively low acoustic impedance; and
the support and the piezoelectric layer are arranged such that at least a portion of the support and at least a portion of the piezoelectric layer face each other with the acoustic reflective film interposed between the support and the piezoelectric layer.
